(19) United States
(12) Patent Application Publication
(10) Pub. No.: US 2017/0141288 A1
(43) Pub. Date: May 18, 2017

(54) VIBRATOR DEVICE, METHOD OF MANUFACTURING VIBRATOR DEVICE, ELECTRONIC APPARATUS, AND MOVING OBJECT

(71) Applicant: Seiko Epson Corporation, Tokyo (JP)

(72) Inventor: Fumio ICHIKAWA, Suwa (JP)

(21) Appl. No.: 15/351,772

(22) Filed: Nov. 15, 2016

(30) Foreign Application Priority Data
Nov. 18, 2015 (JP) 2015-225456

(51) Int. Cl. H01L 41/047; G01C 19/5607; H01L 41/29; H01L 41/187; H01L 41/09

(52) U.S. Cl. CPC H01L 41/0475; H01L 41/1873; H01L 41/09; H01L 41/29; G01C 19/5607

(57) ABSTRACT

A vibrator device includes a first vibration arm (detection arm) that has walls located on both sides with the through hole, which is penetrated through front and rear surfaces, interposed therebetween; and two electrodes in which the walls are arranged on two internal surfaces located on the walls of the through hole, to which mutually different potentials are applied, and which extend in parallel along the front and rear surfaces. Of the electrodes, a first electrode (first detection electrode) located on the front surface side of one of the internal surfaces and a second electrode (second detection electrode) located on the rear surface side of the other internal surface are short-circuited by a first wire disposed on one of end side surfaces connecting the two internal surfaces.

### BACKGROUND

1. Technical Field

The present invention relates to a vibrator device, a method of manufacturing the vibrator device, an electronic apparatus, and a moving object.

2. Related Art

In the related art, for example, an inertia sensor component including vibration arm portions (vibration arms or detection arms) is known as an example of a vibrator device (for example, see JP-A-2006-208261). For example, an inertia sensor component disclosed in JP-A-2006-208261 includes two electrodes that extend along in an extension direction of a vibration arm portion on the same side surfaces as side surfaces connecting the front and rear surfaces (main surfaces) of the vibration arm portion and an electrode that is divided into two electrodes to be formed on internal surfaces of through holes penetrated through the front and rear surfaces of the vibration arm portion. In the vibration arm portion, a total of four electrodes formed two by two on the internal surfaces of the through holes are electrically connected to each other such that the electrodes disposed at diagonal positions are electrically connected (electrified) to each other. The electrodes disposed at the diagonal positions are electrically connected (electrified) by wirings extracting the electrodes to the front and rear surfaces.

However, in the inertia sensor component disclosed in JP-A-2006-208261, it is necessary to extract wires electrifying the electrodes disposed at the diagonal positions on the internal surfaces of the through holes on the front and rear surfaces (main surfaces) narrowed since the through holes are formed. Since the wires are formed in narrow regions of the front and rear surfaces, there is a concern of a defect such as disconnection due to the narrow widths of the wires easily occurring or a defect such as cutting of the wires formed on the front and rear surfaces at the time of frequency adjustment or the like occurring.

### SUMMARY

An advantage of some aspects of the invention is to solve at least a part of the problems described above, and the invention can be implemented as the following forms or application examples.

### Application Example 1

A vibrator device according to this application example includes: a first vibration arm including front and rear surfaces, a through hole that is penetrated through the front and rear surfaces, and walls located on both sides with the through hole interposed therebetween; and each of the walls includes two electrodes arranged on each of two internal surfaces located on the walls of the through hole, to which mutually different potentials are applied, and which extend in parallel along the front and rear surfaces. Of the electrodes, a first electrode located on the front surface side of one of the internal surfaces and a second electrode located on the rear surface side of the other internal surface are short-circuited by a first wire disposed on one of the end side surfaces connecting the two internal surfaces.

According to this application example, the first wire short-circuiting the first electrode located on the front surface side of the one internal surface and the second electrode located on the rear surface side of the other internal surface is disposed on the one end side surface connecting the two internal surfaces. It is not necessary to form wires corresponding to the first wire in narrow regions of the front and rear surfaces because of the disposition of the first wire, and thus it is possible to widen the width of the wire (the first wire) connecting the two internal surfaces. Since the wire is formed on the end side surface present inside the through hole, it is difficult to radiate, for example, a laser beam used at the time of frequency adjustment or the like by comparison of the front and rear surfaces. Thus, it is possible to suppress occurrence of a defect such as cutting of the wires.

### Application Example 2

In the vibrator device according to the application example, it is preferable that the electrodes include a second wire that short-circuits a third electrode located on the front surface side of the one internal surface and a fourth electrode located on the rear surface side of the other internal surface, and the second wire is disposed on the other end side surface connecting the two internal surfaces.

According to this application example, the second wire short-circuiting the third electrode located on the front surface side of the one internal surface and the fourth electrode located on the rear surface side of the other internal surface is disposed on the other end side surface connecting the two internal surfaces. It is not necessary to form wires corresponding to the second wire in narrow regions of the front and rear surfaces because of the disposition of the second wire, and thus it is possible to widen the width of the wire (the second wire) connecting the two internal surfaces. Since the wire is formed on the end side surface present inside the through hole, it is difficult to radiate, for example, a laser beam used at the time of frequency adjustment or the like by comparison of the front and rear surfaces. Thus, it is possible to suppress occurrence of a defect such as cutting of the wires.

### Application Example 3

In the vibrator device according to the application example, it is preferable that a width of the end side surface includes a portion narrower than a width between the two internal surfaces.

According to this application example, it is possible to easily view the end side surface in the width direction of the first vibration arm which is a direction in which the width between the two internal surfaces is defined, and thus it is possible to easily confirm the states in which the first and second wires are formed.

The width of the end side surface in the present specification is said to be a dimension of the end side surface in a direction in which the two internal surfaces are arranged and the width between the internal surfaces is said to be a dimension between the two side surfaces in a direction in which the two internal surfaces are arranged.

### Application Example 4

It is preferable that the vibrator device according to the application example further includes abase; and a second vibration arm that extends from the base. The first vibration arm preferably extends from the base in an opposite direction to an extension direction of the second vibration arm.

According to this application example, when the first vibration arm is set as a detection system and the second vibration arm is set as a driving system, the first vibration arm serving as the detection system and the second vibration arm serving as the driving system extend from both ends of the base in the same axis direction in opposite directions, and thus the driving system and the detection system can be separated. By separating the driving system and the detection system in this way, it is possible to reduce electrostatic bonding between the electrodes or the wires of the driving system and the detection system and it is possible to stabilize detection sensitivity.

### Application Example 5

It is preferable that the vibrator device according to the application example further includes a package that accommodates at least the first vibration arm.

According to this application example, since the first vibration armor the like is accommodated in the package, it is possible to realize the vibrator device in which the vibration characteristics are stabilized.

### Application Example 6

A method of manufacturing a vibrator device according to this application example is a method of manufacturing a vibrator device which includes a first vibrating arm including front and rear surfaces, a through hole that is penetrated through the front and rear surfaces, walls located on both sides with the through hole interposed therebetween, in which each of the walls includes two electrodes arranged on two internal surfaces located on the walls of the through holes, to which mutually different potentials are applied, and which extend in parallel along the front and rear surfaces, in which each of the electrodes includes a first wire short-circuiting a first electrode located on the front surface side of one of the internal surfaces and a second electrode located on the rear surface side of the other internal surface and the first wire is disposed on one of the end side surfaces of the through hole connecting the two internal surfaces. The method includes: forming a metal film on an exposure surface of the first vibration arm in which the through hole is formed; and forming the electrodes by dividing the metal film on the end side surface and the internal surface.

According to this application example, the metal film is formed on the exposed surface of the first vibration arm in which the through hole is formed and the metal film is separated on the end side surface and the internal surface so that the electrodes are formed. Thus, it is possible to easily form the first electrode, the second electrode, and the first wire connecting these electrodes without forming wires in narrow regions of the front and rear surfaces of the first vibration arm. In other words, it is possible to easily form the wire (the first wire) with a broad width by which disconnection of a wire easily occurring in a wire with a narrow width can be suppressed.

### Application Example 7

In the method of manufacturing the vibrator device according to the application example, it is preferable that the forming of the electrodes by dividing the metal film includes an exposure process performed 4 times.

According to this application example, by dividing the metal film through the exposure process performed 4 times and forming the electrodes, it is possible to divide the metal film more reliably. In other words, it is possible to suppress a defect of the division in the forming of the electrodes.

### Application Example 8

An electronic apparatus according to this application example includes the vibrator device according to any one of the application examples.

According to this application example, since the vibrator device in which characteristics are stabilized by suppressing the defect such as cutting of a wire connecting electrodes is included, it is possible to provide the electronic apparatus in which performance is stabilized.

### Application Example 9

A moving object according to this application example includes the vibrator device according to any one of the application examples.

According to this application example, since the vibrator device in which characteristics are stabilized by suppressing the defect such as cutting of a wire connecting electrodes is included, it is possible to provide the moving object in which performance is stabilized.

### BRIEF DESCRIPTION OF THE DRAWINGS

The invention will be described with reference to the accompanying drawings, wherein like numbers reference like elements.

FIG. 1 is a plan view illustrating an overview of a gyro element (H type gyro element) serving as a vibrator component according to a first embodiment of a vibrator device according to the invention.

FIG. 2 is a diagram illustrating an electrode configuration of the gyro element (H type gyro element) and a sectional view taken along the line A-A of FIG. 1 according to the first embodiment.

FIG. 3 is a diagram illustrating an electrode configuration of the gyro element (H type gyro element) and a sectional view taken along the line B-B of FIG. 1 according to the first embodiment.

FIG. 4 is a diagram illustrating an electrode configuration of the gyro element (H type gyro element) and a sectional view taken along the line C-C of FIG. 1 according to the first embodiment.

FIG. 5 is a diagram illustrating an electric connection state of electrodes formed in detection arms.

FIG. 6 is a flowchart illustrating processes of a method of manufacturing the gyro element (H type gyro element) according to the first embodiment.

FIG. 7A is a sectional view illustrating an exposure direction in the method of manufacturing the gyro element (H type gyro element) and taken along the line A-A of FIG. 1 in one detection arm according to the first embodiment.

FIG. 7B is a sectional view illustrating an exposure state at ends of through holes.

FIG. 8 is a partial plan view illustrating an overview of a gyro element (H type gyro element) serving as a vibrator component according to a second embodiment of the vibrator device according to the invention.

FIG. 9 is a flowchart illustrating steps of a method of manufacturing the gyro element (H type gyro element) according to the second embodiment.

FIG. 10A is a sectional view illustrating an exposure direction in the method of manufacturing the gyro element (H type gyro element) and taken along the line A-A of FIG. 1 in one detection arm according to the second embodiment.

FIG. 10B is a sectional view illustrating an exposure direction and taken along the line D-D of FIG. 8 in one detection arm.

FIG. 10C is a sectional view illustrating an exposure state at ends of through holes.

FIG. 11 is a front sectional view illustrating an overall configuration of a gyro sensor according to a third embodiment of the vibrator device according to the invention.

FIG. 12 is a perspective view illustrating the configuration of a mobile personal computer which is an example of an electronic apparatus.

FIG. 13 is a perspective view illustrating the configuration of a mobile phone which is an example of an electronic apparatus.

FIG. 14 is a perspective view illustrating the configuration of a digital still camera which is an example of an electronic apparatus.

FIG. 15 is a perspective view illustrating an automobile which is an example of a moving object.

### DESCRIPTION OF EXEMPLARY EMBODIMENTS

Hereinafter, embodiments of a vibrator device, an electronic apparatus, and a moving object according to the invention will be described in detail with reference to the drawings. In the drawings, X, Y, and Z axes which are three axes orthogonal to each other are illustrated to facilitate the description. In the present specification, three axes are indicated as X, Y, and Z axes in consideration of a cutout angle of a vibrator element in each embodiment. In the following description, a plan view when viewed in the Z axis direction in the drawing is simply referred to as a “plan view” to facilitate the description. Further, to facilitate the description, in the plan view when viewed in the Z axis direction in the drawing, a surface in the +Z axis direction is referred to as a front surface and a surface in the −Z axis direction is referred to as a rear surface in some cases in the following description.

### First Embodiment

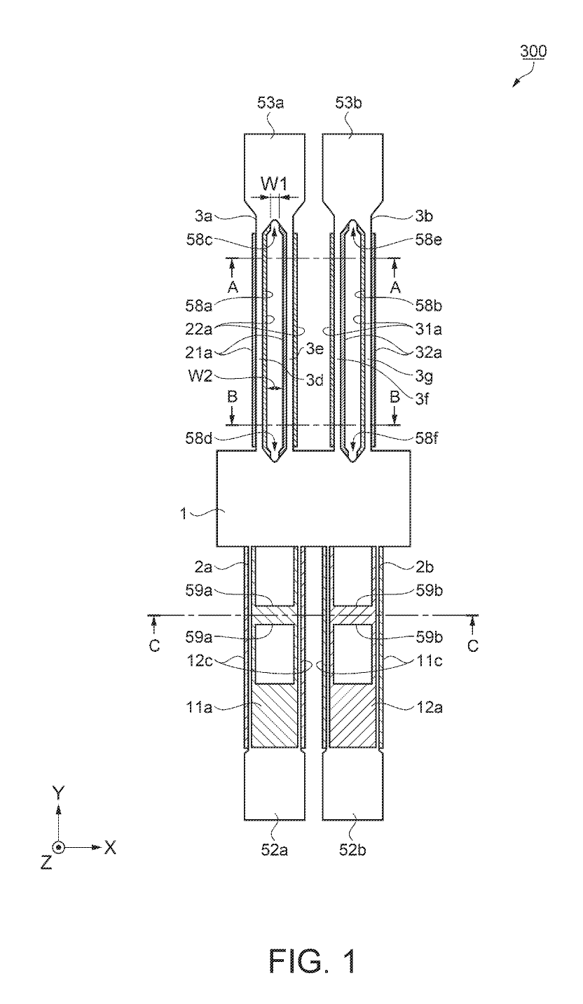

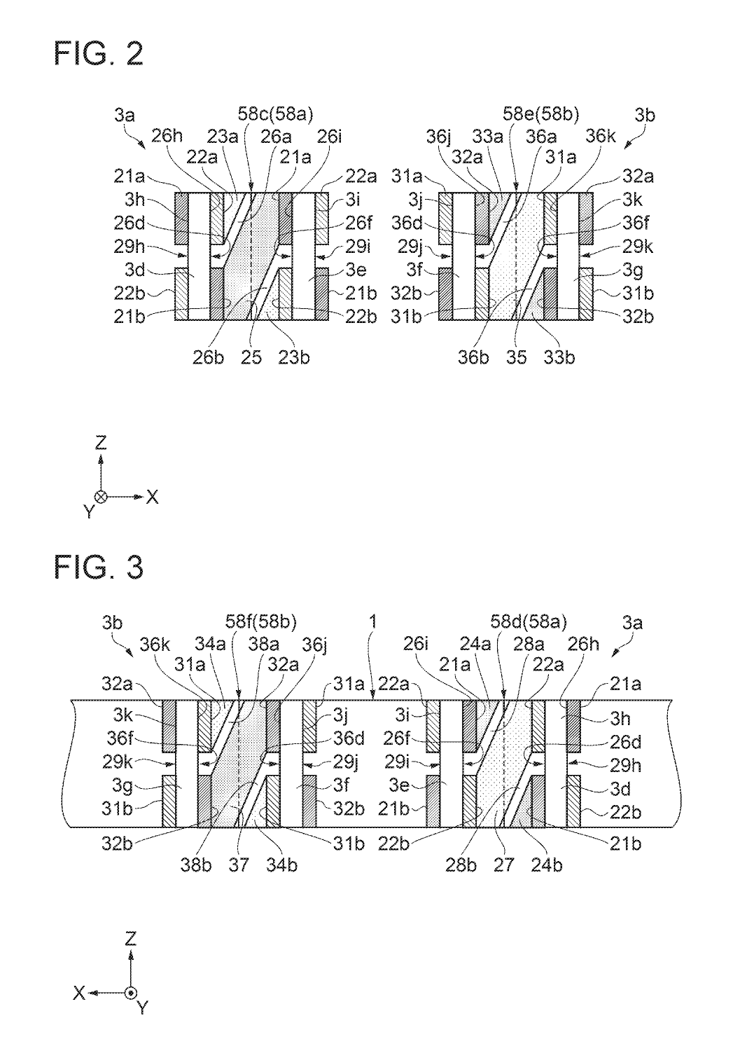

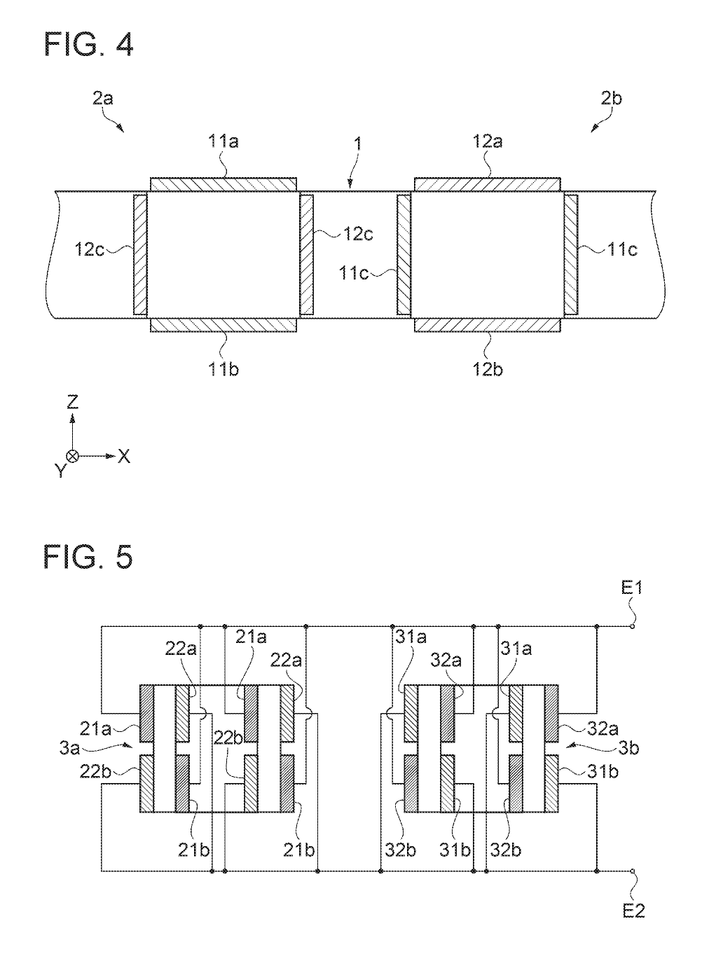

A gyro element (H type gyro element) serving as a vibrator component according to a first embodiment of the vibrator device according to the invention will be described. First, the configuration of the gyro element (H type gyro element) serving as the vibrator component will be described with reference to FIGS. 1, 2, 3, 4, and 5. FIG. 1 is a plan view illustrating an overview of the gyro element (H type gyro element) serving as the vibrator component according to the first embodiment of the vibrator device. FIG. 2 is a diagram illustrating an electrode configuration of the gyro element (H type gyro element) and a sectional view taken along the line A-A of FIG. 1. FIG. 3 is a diagram illustrating an electrode configuration of the gyro element (H type gyro element) and a sectional view taken along the line B-B of FIG. 1. FIG. 4 is a diagram illustrating an electrode configuration of the gyro element (H type gyro element) and a sectional view taken along the line C-C of FIG. 1. FIG. 5 is a diagram illustrating an electric connection state of electrodes formed in detection arms of the gyro element (H type gyro element) and a diagram corresponding to the sectional view taken along the line A-A of FIG. 1.

### 1. Configuration of Gyro Element

As illustrated in FIGS. 1 and 2, a gyro element 300 according to the first embodiment includes abase 1, vibration arms 2a and 2b serving as a second vibration arm and detection arms 3a and 3b serving as a first vibration arm. The base 1, the vibration arms 2a and 2b, and the detection arms 3a and 3b are formed in an integrated manner by processing a base material (a material of main portions).

In the gyro element 300 according to the embodiment, an example in which quartz crystal which is a piezoelectric material is used as the base material will be described. The quartz crystal has an X axis called an electric axis, a Y axis called a mechanical axis, and a Z axis called an optical axis. In the embodiment, a so-called quartz crystal Z plate that is cut along a plane defined the X and Y axes orthogonal to a quartz crystal axis to be processed in a flat plate shape and has a predetermined thickness in the Z axis direction perpendicular to the plane is used as a base material. For a flat plate on which the gyro element 300 is formed, an error of a cutout angle from the quartz crystal can be permitted in few ranges with respect to the X, Y, and Z axes. For example, a flat plate cut out by rotating the quartz crystal about on the X axis in the range of 0 degrees to 2 degrees can be used. The same applies to the Y and Z axes.

The gyro element 300 includes the base 1 that is located at a center of the gyro element 300 and has a substantially rectangular shape, a pair of vibration arms 2a and 2b (the second vibration arm) that extend from one end of the base 1 in the Y axis direction (an end in the −Y axis direction in the drawing) in parallel along the Y axis, and a pair of detection arms 3a and 3b (the first vibration arm) that extend from the other end of the base 1 (the end in the +Y axis direction in the drawing) to be parallel along the Y axis. In other words, the vibration arms 2a and 2b extend from the base 1 in the opposite direction (−Y axis direction) to the extension direction (the +Y axis direction) of the detection arms 3a and 3b. In this way, the pair of vibration arms 2a and 2b and the pair of detection arms 3a and 3b extend from both ends of the base 1 in the opposite directions along the axis direction. From the viewpoint of this shape, the gyro element 300 according to the embodiment is also referred to as an H type gyro element. In the H type gyro element 300, a driving system and a detection system are separated since the vibration arms 2a and 2b serving as the second vibration arm and the detection arms 3a and 3b serving as the first vibration arm extend from both ends of the base 1 in the same axis direction. Since the driving system and the detection system are separated in this way, the gyro element 300 has characteristics in which electrostatic bonding between electrodes or wires of the driving system and the detection system is reduced and detection sensitivity is stabilized. In the embodiment, for example, two vibration arms and two detection arms are formed in the H type vibrator element, but the number of vibration arms may be 1 or 3 or more. Drive electrodes and detection electrodes to be described below may be formed in one vibration arm.

In the H type gyro element 300, a Coriolis force is generated in the vibration arms 2a and 2b when an angular velocity ω is applied around the Y axis in a state in which the pair of vibration arms 2a and 2b are vibrated in an in-plane direction (the +X axis direction and the −X axis direction) at a predetermined resonance frequency. Then, the vibration arms 2a and 2b perform flexural vibration in mutually opposite directions in the out-of-plane direction (the +Z axis direction and the −Z axis direction) intersecting the in-plane direction. Then, the detection arms 3a and 3b resonate with the flexural vibration in the out-of-plane direction of the vibration arms 2a and 2b and perform flexural vibration in the out-of-plane direction similarly. At this time, charges are generated in detection electrodes formed in the detection arms 3a and 3b by the piezoelectric effect. The gyro element 300 can detect the angular velocity ω added to the gyro element 300 by detecting the charges.

The pair of vibration arms 2a and 2b (the second vibration arm) extending from the base 1 are vibration arms of the driving system and include a front surface, a rear surface formed on the opposite side of the front surface, and side surfaces connecting the rear surface and the front surface, as illustrated in FIG. 4. The vibration arms 2a and 2b include through holes 59a and 59b. The through holes 59a and 59b are disposed to be arranged in the extension direction (the Y axis direction) of the vibration arms 2a and 2b two by two. Further, weights 52a and 52b that has a substantially rectangular shape with a width (a size in the X axis direction is larger) broader than the vibration arms 2a and 2b are formed at a front end located on the other end side opposite to the one end of the vibration arms 2a and 2b on the side of the base 1 (see FIG. 1). When the weights 52a and 52b are formed in the vibration arms 2a and 2b in this way, predetermined driving vibration can be obtained while suppressing an increase in the lengths of the vibration arms 2a and 2b (the sizes in the Y axis direction), and thus it is possible to miniaturize the gyro element. Electrodes are formed in the vibration arms 2a and 2b to drive the vibration arms 2a and 2b. The configuration of the electrodes will be described below.

The pair of detection arms 3a and 3b (the first vibration arm) extending from the base 1 are vibration arms of the detection system and includes a front surface, a rear surface formed on the opposite side of the front surface, and side surfaces 3h, 3i, 3j, and 3k, connecting the front and rear surfaces, as illustrated in FIG. 2. Further, in the detection arms 3a and 3b, weights 53a and 53b that has a substantially rectangular shape with a width (a size in the X axis direction is larger) broader than the detection arms 3a and 3b are formed as portions with a large width at a front end located on the other end side opposite to the one end on the side of the base 1 (see FIG. 1). When the weights 53a and 53b are formed in the detection arms 3a and 3b in this way, predetermined detection vibration can be obtained while suppressing an increase in the lengths of the detection arms 3a and 3b (the sizes in the Y axis direction), and thus it is possible to miniaturize the gyro element 300.

Through holes 58a and 58b are formed in the pair of detection arms 3a and 3b. Specifically, the through hole 58a is formed in one detection arm 3a and the through hole 58b is formed in the other detection arm 3b. The through holes 58a and 58b are penetrated through the front and rear surfaces of the detection arms 3a and 3b and are arranged from the vicinities of connection portions with the base 1 to the vicinities of connection portions with the weights 53a and 53b in the extension direction (the Y axis direction) of the detection arms 3a and 3b. The through holes 58a and 58b are penetrated through the front and rear surfaces in the middles of the pair of detection arms 3a and 3b in a plan view. In the detection arms 3a and 3b, walls 3d, 3e, 3f, and 3g are formed on both sides in the width direction (the X axis direction) by the through holes 58a and 58b with the through holes 58a and 58b interposed therebetween. Specifically, the detection arm 3a includes the walls 3d and 3e on both sides with the through hole 58a interposed therebetween. The detection arm 3b includes the walls 3f and 3g on both sides with the through hole 58b interposed therebetween. The through holes 58a and 58b include first end portions located on the side of the base 1 and second end portions located on the opposite side (the side of the weights 53a and 53b) to the first end portions. The first end portions include end side surfaces 58d and 58f which are the other end side surfaces and the second end portions include end side surfaces 58c and 58e which are one end side surfaces. The end side surfaces 58c, 58d, 58e, and 58f are surfaces that connect two internal surfaces of the through holes 58a and 58b facing each other in the extension direction (the Y axis direction) in the internal surfaces of the through holes 58a and 58b and are said to be portions of the internal surfaces located in the first and second end portions.

In this form, in the through holes 58a and 58b, a width W2 which is a width dimension between two internal surfaces facing each other in the extension direction (the Y axis direction) of each of the through holes 58a and 58b in a plan view is formed to be narrowed from the first end portion to the second end portion. Specifically, the first and second portions include the end side surfaces 58c, 58d, 58e, and 58f which have portions with a width W1 which is a width dimension narrower than the width W2 between two internal surfaces facing each other in the extension direction (the Y axis direction) of the through holes 58a and 58b. The width (width dimension) in the widths W1 and W2 is said to be a direction in which two internal surfaces are arranged, that is, a dimension in a direction (the X axis direction) perpendicular to the extension direction (the Y axis direction) of the through holes 58a and 58b.

The end side surfaces 58c, 58d, 58e, and 58f extend in the extension direction (the Y axis direction) of the through holes 58a and 58b and has two surfaces with a gradually decreasing interval so that two facing internal surfaces are connected at one end or the other end. In other words, in the first and second ends, a portion in which each of the end side surfaces 58c, 58d, 58e, and 58f is formed has a shape corresponding to two sides of a triangle in a plan view.

When the end side surfaces 58c, 58d, 58e, and 58f are included, the end side surfaces 58c, 58d, 58e, and 58f can be viewed easily in the width direction (the X axis direction) of the detection arms 3a and 3b which is a direction in which the width between two internal surfaces is regulated. Thus, it is possible to easily confirm states (quality) in which first wires 25 and 35 (see FIGS. 2 and 3) and second wires 27 and 37 (see FIGS. 2 and 3) to be described below are formed.

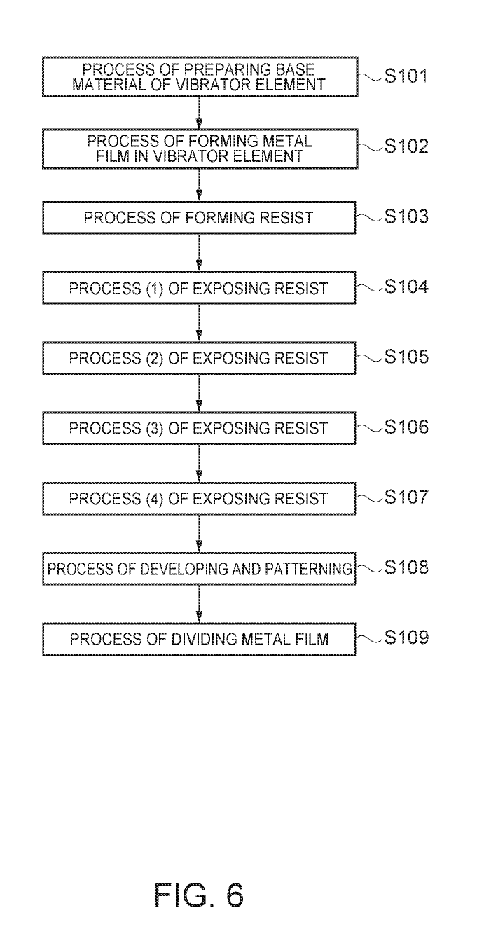

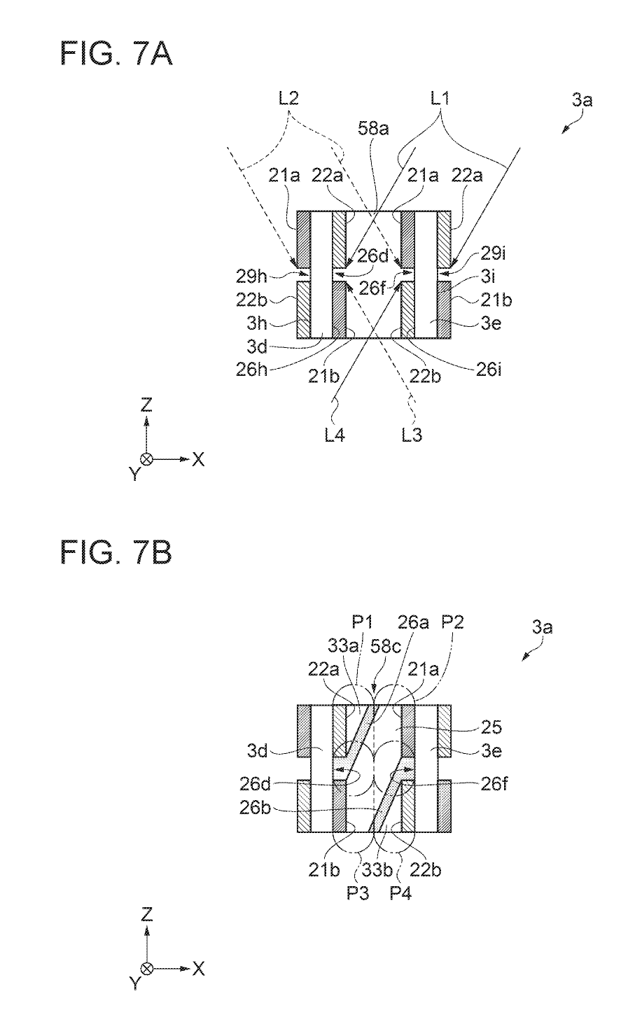

In a manufacturing method to be described below, pieces of exposure light L1 and L2 (see FIGS. 7A and 7B) can be easily radiated in a process (see FIG. 6) of exposing resists used to form the first wires 25 and 35 and the second wires 27 and 37. Thus, in the manufacturing method, the process of exposing the resists can be simplified.

The end side surfaces 58c, 58d, 58e, and 58f may be faced to be viewed in the width direction (the X axis direction) of the detection arms 3a and 3b. A polygonal shape, a curved shape, a combined shape of a curved line and a straight line, or the like can be applied.

The middle of the base 1 can serve as a center of the gyro element 300. The X, Y, and Z axes are assumed to orthogonal to each other and pass through the center. The external shape of the gyro element 300 has line symmetry with respect to an imaginary central line passing through the center in the Y axis direction. Thus, the line symmetry is desirable since the external shape of the gyro element 300 is well balanced, characteristics of the gyro element 300 are stabilized, and detection sensitivity is improved. The external shape of the gyro element 300 can be formed by etching (wet etching or dry etching) in which a photolithographic technology is used. The plurality of gyro elements 300 can be obtained from one quartz crystal wafer.

### 2. Electrode Disposition of Gyro Element

Next, an embodiment of electrode disposition of the gyro element 300 will be described with reference to FIGS. 2, 3, 4, and 5.

First, detection electrodes which are formed in the detection arms 3a and 3b and detect distortion occurring in the quartz crystal which is a base material due to vibration of the detection arms 3a and 3b will be described. As illustrated in FIG. 2, as described above, the front and rear surfaces, the side surfaces 3h, 3i, 3j, and 3k connecting the front and rear surfaces, and the through holes 58a and 58b penetrated through the front and rear surfaces in the middle of the detection arms 3a and 3b in a plan view are formed in the detection arms 3a and 3b.

In the detection arm 3a, a first detection electrode 21a on the front surface side and a fourth detection electrode 22b on the rear surface side which are divided by electrode division portion 29h formed in the extension direction (the Y axis direction) of the detection arm 3a in the substantial middle of the detection arm 3a in the thickness direction (the Z axis direction) are formed on the side surface 3h on the side of the wall 3d. In other words, two electrodes (the first detection electrode 21a and the fourth detection electrode 22b) extending in parallel along the front and rear surfaces are formed on the side surface 3h of the detection arm 3a. In this way, the first detection electrode 21a is an electrode located on the front surface side of the side surface 3h and the fourth detection electrode 22b is an electrode located on the rear surface side of the side surface 3h in the detection arm 3a.

Further, in the detection arm 3a, a third detection electrode 22a on the front surface side and a second detection electrode 21b on the rear surface side which are divided by an electrode division portion 26d formed in the extension direction (the Y axis direction) of the detection arm 3a in the substantial middle of the detection arm 3a in the thickness direction (the Z axis direction) are formed on the internal surface 26h on the side of the wall 3d of the through hole 58a facing the first detection electrode 21a and the fourth detection electrode 22b formed on the side surface 3h. In this form, the third detection electrode 22a located on the internal surface 26h on the side of the wall 3d corresponds to a third electrode in SUMMARY and the second detection electrode 21b corresponds to a second electrode in SUMMARY. In other words, two electrodes (the third detection electrode 22a serving as the third electrode and the second detection electrode 21b serving as the second electrode on the rear surface side) extending in parallel along the front and rear surfaces are formed on the internal surface 26h on the side of the wall 3d of the through hole 58a. In this way, the third detection electrode 22a serving as the third electrode is an electrode located on the front surface side of the internal surface 26h of the through hole 58a and the second detection electrode 21b serving as the second electrode is an electrode located on the rear surface side of the internal surface 26h.

In the detection arm 3a, the third detection electrode 22a on the front surface side and the second detection electrode 21b on the rear surface side which are divided by an electrode division portion 29i formed in the extension direction (the Y axis direction) of the detection arm 3a in the substantial middle of the detection arm 3a in the thickness direction are formed on the side surface 3i on the side of the wall 3e opposite to the side surface 3h. In other words, two electrodes (the third detection electrode 22a and the second detection electrode 21b) extending in parallel along the front and rear surfaces are formed on the side surface 3i of the detection arm 3a. In this way, the third detection electrode 22a is an electrode located on the front surface side of the side surface 3i in the detection arm 3a and the second detection electrode 21b is an electrode located on the rear surface side of the side surface 3i.

Further, in the detection arm 3a, the first detection electrode 21a on the front surface side and the fourth detection electrode 22b on the rear surface side which are divided by an electrode division portion 26f formed in the extension direction (the Y axis direction) of the detection arm 3a in the substantial middle of the detection arm 3a in the thickness direction (the Z axis direction) are formed on the internal surface 26i on the side of the wall 3e of the through hole 58a facing the third detection electrode 22a and the second detection electrode 21b formed on the side surface 3i. In this form, the first detection electrode 21a located on the internal surface 26i on the side of the wall 3e corresponds to the first electrode in SUMMARY and the fourth detection electrode 22b corresponds to the fourth electrode in SUMMARY. In other words, two electrodes (the first detection electrode 21a serving as the first electrode and the fourth detection electrode 22b serving as the fourth electrode on the rear surface side) extending in parallel along the front and rear surfaces are formed on the internal surface 26i on the side of the wall 3e of the through hole 58a. In this way, the first detection electrode 21a serving as the first electrode is an electrode located on the front surface side of the internal surface 26i of the through hole 58a and the fourth detection electrode 22b serving as the fourth electrode is an electrode located on the rear surface side of the internal surface 26i.

The first detection electrode 21a located on the front surface side of the internal surface 26i of the through hole 58a and the second detection electrode 21b located on the rear surface side of the internal surface 26h of the through hole 58a are electrically connected (short-circuited) by the first wire 25 formed on one end side surface 58c connecting the internal surfaces 26h and 26i. The first wire 25 connects the first detection electrode 21a located on the front surface side of the internal surface 26i to the second detection electrode 21b located on the rear surface side of the other internal surface 26h and is disposed to be oblique in the one end side surface 58c. In the one end side surface 58c, end side surface electrodes 23a and 23b which are electrodes divided by the first wire 25 and electrode division portions 26a and 26b may be formed in addition to the first wire 25. The electrode division portions 26a and 26b are preferably disposed to reach the front and rear surfaces of the detection arm 3a in the middle of the end side surface 58c in the X direction. By disposing the electrode division portions 26a and 26b in this way, it is possible to exposure the electrode division portions 26a and 26b through one-time exposure from the oblique upper side or the oblique lower side, and thus it is possible to simplify a process of exposing resists in a manufacturing method to be described below.

As illustrated in FIG. 3, the third detection electrode 22a located on the front surface side of the internal surface 26h of the through hole 58a and the fourth detection electrode 22b located on the rear surface side of the other internal surface 26i of the through hole 58a are electrically connected (short-circuited) by the second wire 27 formed on the other end side surface 58d connecting the internal surfaces 26h and 26i. The second wire 27 connects the third detection electrode 22a located on the front surface side of the internal surface 26h to the fourth detection electrode 22b located on the rear surface side of the other internal surface 26i and is disposed to be oblique in the other end side surface 58d. In the other end side surface 58d, end side surface electrodes 24a and 24b which are other electrodes divided by the second wire 27 and electrode division portions 28a and 28b may be formed in addition to the second wire 27. The electrode division portions 28a and 28b are preferably disposed to reach the front and rear surfaces of the detection arm 3a in the middle of the end side surface 58d in the X direction. By disposing the electrode division portions 28a and 28b in this way, it is possible to exposure the electrode division portions 28a and 28b through one-time exposure from the oblique upper side or the oblique lower side, and thus it is possible to simplify a process of exposing resists in a manufacturing method to be described below.

The first detection electrode 21a and the second detection electrode 21b, and the third detection electrode 22a and the fourth detection electrode 22b are electrically connected to external connection pads (not illustrated) via wires (not illustrated).

Similarly, in the detection arm 3b illustrated in FIG. 2, a fifth detection electrode 31a on the front surface side and an eighth detection electrode 32b on the rear surface side which are divided by an electrode division portion 29j formed in the extension direction (the Y axis direction) of the detection arm 3b in the substantial middle of the detection arm 3b in the thickness direction (the Z axis direction) are formed on the side surface 3j on the side of the wall 3f. In other words, two electrodes (the fifth detection electrode 31a and the eighth detection electrode 32b) extending in parallel along the front and rear surfaces are formed on the side surface 3j of the detection arm 3b. In this way, the fifth detection electrode 31a is an electrode located on the front surface side of the side surface 3j in the detection arm 3b and the eighth detection electrode 32b is an electrode located on the rear surface side of the side surface 3j.

Further, in the detection arm 3b, a seventh detection electrode 32a on the front surface side and a sixth detection electrode 31b on the rear surface side which are divided by an electrode division portion 36d formed in the extension direction (the Y axis direction) of the detection arm 3b in the substantial middle of the detection arm 3b in the thickness direction (the Z axis direction) are formed on the internal surface 36j on the side of the wall 3f of the through hole 58b facing the fifth detection electrode 31a and the eighth detection electrode 32b formed on the side surface 3j . In this form, the seventh detection electrode 32a located on the internal surface 36j on the side of the wall 3f corresponds to a third electrode in SUMMARY and the sixth detection electrode 31b corresponds to a second electrode in SUMMARY. In other words, two electrodes (the seventh detection electrode 32a serving as the third electrode and the sixth detection electrode 31b serving as the second electrode on the rear surface side) extending in parallel along the front and rear surfaces are formed on the internal surface 36j on the side of the wall 3f of the through hole 58b. In this way, the seventh detection electrode 32a serving as the third electrode is an electrode located on the front surface side of the internal surface 36j of the through hole 58b and the sixth detection electrode 31b serving as the second electrode is an electrode located on the rear surface side of the internal surface 36j.

In the detection arm 3b, the seventh detection electrode 32a on the front surface side and the sixth detection electrode 31b on the rear surface side which are divided by an electrode division portion 29k formed in the extension direction (the Y axis direction) of the detection arm 3b in the substantial middle of the detection arm 3b in the thickness direction are formed on the side surface 3k on the side of the wall 3g opposite to the side surface 3j. In other words, two electrodes (the seventh detection electrode 32a and the sixth detection electrode 31b) extending in parallel along the front and rear surfaces are formed on the side surface 3k of the detection arm 3b. In this way, the seventh detection electrode 32a is an electrode located on the front surface side of the side surface 3k in the detection arm 3b and the sixth detection electrode 31b is an electrode located on the rear surface side of the side surface 3k.

Further, in the detection arm 3b, the fifth detection electrode 31a on the front surface side and the eighth detection electrode 32b on the rear surface side which are divided by an electrode division portion 36f formed in the extension direction (the Y axis direction) of the detection arm 3b in the substantial middle of the detection arm 3b in the thickness direction (the Z axis direction) are formed on the internal surface 36k on the side of the wall 3g of the through hole 58b facing the seventh detection electrode 32a and the sixth detection electrode 31b formed on the side surface 3k. In this form, the fifth detection electrode 31a located on the internal surface 36k on the side of the wall 3g corresponds to the first electrode in SUMMARY and the eighth detection electrode 32b corresponds to the fourth electrode in SUMMARY. In other words, two electrodes (the fifth detection electrode 31a serving as the first electrode and the eighth detection electrode 32b serving as the fourth electrode on the rear surface side) extending in parallel along the front and rear surfaces are formed on the internal surface 36k on the side of the wall 3g of the through hole 58b. In this way, the fifth detection electrode 31a serving as the first electrode is an electrode located on the front surface side of the internal surface 36k of the through hole 58b and the eighth detection electrode 32b serving as the second electrode is an electrode located on the rear surface side of the internal surface 36k.

The fifth detection electrode 31a located on the front surface side of the internal surface 36k of the through hole 58b and the sixth detection electrode 31b located on the rear surface side of the internal surface 36j of the through hole 58b are electrically connected (short-circuited) by the first wire 35 formed on one end side surface 58e connecting the internal surfaces 36j and 36k. The first wire 35 connects the fifth detection electrode 31a located on the front surface side of the internal surface 36k to the sixth detection electrode 31b located on the rear surface side of the other internal surface 36j and is disposed to be oblique in the one end side surface 58e. In the one end side surface 58e, end side surface electrodes 33a and 33b which are electrodes divided by the first wire 35 and electrode division portions 36a and 36b may be formed in addition to the first wire 35. The electrode division portion 36a is connected to the electrode division portion 36d and the electrode division portion 36b is connected to the electrode division portion 36f. The electrode division portions 36a and 36b are preferably disposed to reach the front and rear surfaces of the detection arm 3b in the middle of the end side surface 58e in the X direction. By disposing the electrode division portions 36a and 36b in this way, it is possible to exposure the electrode division portions 36a and 36b through one-time exposure from the oblique upper side or the oblique lower side, and thus it is possible to simplify a process of exposing resists in a manufacturing method to be described below.

As illustrated in FIG. 3, the seventh detection electrode 32a located on the front surface side of the internal surface 36j of the through hole 58b and the eighth detection electrode 32b located on the rear surface side of the other internal surface 36k of the through hole 58b are electrically connected (short-circuited) by the second wire 37 formed on the other end side surface 58f connecting the internal surfaces 36j and 36k. The second wire 37 connects the seventh detection electrode 32a located on the front surface side of the internal surface 36j to the eighth detection electrode 32b located on the rear surface side of the other internal surface 36k and is disposed to be oblique in the other end side surface 58f. In the other end side surface 58f, end side surface electrodes 34a and 34b which are other electrodes divided by the second wire 27 and electrode division portions 38a and 38b may be formed in addition to the second wire 37. The electrode division portion 38a is connected to the electrode division portion 36f and the electrode division portion 38b is connected to the electrode division portion 36d. The electrode division portions 38a and 38b are preferably disposed to reach the front and rear surfaces of the detection arm 3b in the middle of the end side surface 58f in the X direction. By disposing the electrode division portions 38a and 38b in this way, it is possible to exposure the electrode division portions 38a and 38b through one-time exposure from the oblique upper side or the oblique lower side, and thus it is possible to simplify a process of exposing resists in a manufacturing method to be described below.

The fifth detection electrode 31a and the sixth detection electrode 31b, and the seventh detection electrode 32a and the eighth detection electrode 32b are electrically connected to external connection pads (not illustrated) via wires (not illustrated).

Here, an electric connection state of the electrodes formed in the detection arms 3a and 3b will be described with reference to FIG. 5. In the detection arm 3a, as illustrated in FIG. 5, the first detection electrode 21a and the second detection electrode 21b are connected to have the same potential, and the third detection electrode 22a and the fourth detection electrode 22b are connected to have the same potential. Specifically, the first detection electrode 21a and the second detection electrode 21b are connected to a connection terminal E1, and the third detection electrode 22a and the fourth detection electrode 22b are connected to the connection terminal E2. Distortion occurring by vibration of the detection arm 3a can be detected by detecting a potential difference between the first detection electrode 21a and the second detection electrode 21b, and the third detection electrode 22a and the fourth detection electrode 22b.

Similarly, in the detection arm 3b, the fifth detection electrode 31a and the sixth detection electrode 31b are connected to have the same potential, and the seventh detection electrode 32a and the eighth detection electrode 32b are connected to have the same potential. Specifically, the fifth detection electrode 31a and the sixth detection electrode 31b are connected to a connection terminal E2, and the seventh detection electrode 32a and the eighth detection electrode 32b are connected to the connection terminal E1. Distortion occurring by vibration of the detection arm 3b can be detected by detecting a potential difference between the fifth detection electrode 31a and the sixth detection electrode 31b, and the seventh detection electrode 32a and the eighth detection electrode 32b.

Next, drive electrodes 11a, 11b, 11c, 12a, 12b, and 12c that are formed in the vibration arms 2a and 2b and drive the vibration arms 2a and 2b will be described with reference to FIG. 4. As illustrated in FIG. 4, the drive electrode 11a is formed on the front surface (one main surface) of the vibration arm 2a up to the weight 52a (see FIG. 1) and the drive electrode 11b is formed on the rear surface (the other main surface) up to the weight 52a. The drive electrodes 12c are formed on one side and the other side of the vibration arm 2a up to the weight 52a (see FIG. 1) of the vibration arm 2a. Similarly, the drive electrode 12a is formed on the front surface (one main surface) of the vibration arm 2b up to the weight 52b (see FIG. 1) and the drive electrode 12b is formed on the rear surface (the other main surface) up to the weight 52b. The drive electrodes 11c are formed on one side and the other side of the vibration arm 2b up to the weight 52b (see FIG. 1) of the vibration arm 2b.

The drive electrodes 11a, 11b, 11c, 12a, 12b, and 12c formed in the vibration arms 2a and 2b are disposed to face each other via the vibration arms 2a and 2b so that the drive electrodes 11a, 11b, and 11c have the same potential and the drive electrodes 12a, 12b, and 12c have the same potential different from the potential of the drive electrodes 11a, 11b, and 11c. Although not illustrated, so-called flexural vibration of the vibration arms 2a and 2b are excited by alternately applying a potential difference between the drive electrodes 11a, 11b, and 11c and the drive electrodes 12a, 12b, and 12c through a connection pad formed in a first fixing portion to which the drive electrodes 11a, 11b, and 11c are connected and a connection pad formed in a second fixing portion to which the drive electrodes 12a, 12b, and 12c are connected.

The configurations of the drive electrodes 11a, 11b, 11c, 12a, 12b, and 12c, the first detection electrode 21a, the second detection electrode 21b, the third detection electrode 22a, the fourth detection electrode 22b, the fifth detection electrode 31a, the sixth detection electrode 31b, the seventh detection electrode 32a, the eighth detection electrode 32b, the first wires 25 and 35, and the second wires 27 and 37 described above are not particularly limited, but may have conductivity and may be formed as thin films. As specific configurations, the electrodes and the wires can be formed of, for example, a conductive material such as indium tin oxide (ITO) or a metal material such as gold (Au), a gold alloy, platinum (Pt), aluminum (Al), an aluminum alloy, silver (Ag), a silver alloy, chromium (Cr), a chromium alloy, copper (Cu), molybdenum (Mo), niobium (Nb), tungsten (W), iron (Fe), titanium (Ti), cobalt (Co), zinc (Zn), or zirconium (Zr).

In this form, the gyro element 300 is formed of quartz crystal, for example. Any of various piezoelectric single-crystal materials such as lithium tantalate and lithium niobate can be used in addition to quartz crystal.

In the gyro element 300 serving as the vibrator component according to the first embodiment, the first wires 25 and 35 short-circuiting the first electrodes (the first detection electrode 21a and the fifth detection electrode 31a) located on the front surface side of the one internal surfaces 26i and 36k of the through holes 58a and 58b formed in the vibration arms 3a and 3b and the second electrodes (the second detection electrode 21b and the sixth detection electrode 31b) located on the rear surface side of the other internal surfaces 26h and 36j are disposed on the one end side surfaces 58c and 58e connecting the two internal surfaces 26h and 26i and the two internal surfaces 36j and 36k. In this way, since the first wires 25 and 35 are disposed on the end side surfaces 58c and 58e of the through holes 58a and 58b, it is not necessary to form wires corresponding to the first wires 25 and 35 in narrow regions of the front and rear surfaces, and thus it is possible to widen the widths of the wires (the first wires 25 and 35) connecting the electrodes formed in the two internal surfaces 26h and 26i and the two internal surfaces 36j and 36k. Since the wires (the first wires 25 and 35) are formed on the end side surfaces 58c and 58e present inside the through holes 58a and 58b, it is difficult to radiate, for example, a laser beam used at the time of frequency adjustment or the like by comparison of the front and rear surfaces. Thus, it is possible to suppress occurrence of a defect such as cutting of the wires.

Further, the second wires 27 and 37 short-circuiting the third electrodes (the third detection electrode 22a and the seventh detection electrode 32a) located on the front surface side of the other internal surface 26h and 36j of the through holes 58a and 58b formed in the vibration arms 3a and 3b and the fourth electrodes (the fourth detection electrodes 22b and the eighth detection electrode 32b) located on the rear surface side of the one internal surface 26i and 36k are disposed on the other end side surfaces 58d and 58f connecting the two internal surfaces 26h and 26i and the two internal surfaces 36j and 36k. In this way, when the second wires 27 and 37 are disposed on the end side surfaces 58d and 58f of the through holes 58a and 58b, it is not necessary to form wires corresponding to the second wires 27 and 37 in narrow regions of the front and rear surfaces, and the widths of the wires (the second wires 27 and 37) connecting the electrodes formed in the two internal surfaces 26h and 26i and the two internal surfaces 36j and 36k can be widened. Since the wires (the second wires 27 and 37) are formed on the end side surfaces 58d and 58f present inside the through holes 58a and 58b, it is difficult to radiate, for example, a laser beam used at the time of frequency adjustment or the like by comparison of the front and rear surfaces. Thus, it is possible to suppress occurrence of a defect such as cutting of the wires.

It is possible to easily view the surfaces of the end side surfaces 58c and 58d in the width directions of the detection arms 3a and 3b which are directions in which the widths between the two internal surfaces 26h and 26i and the two internal surfaces 36j and 36k are defined. Thus, it is possible to easily confirm the formation states of the first wires 25 and 35 and the second wires 27 and 37.

When the first vibration arm is set as a detection system and the second vibration arm is set as a driving system, the first vibration arm (the detection arms 3a and 3b) serving as the detection system and the second vibration arm (the vibration arms 2a and 2b) serving as the driving system extend from both ends of the base 1 in the same axis direction (the Y axis direction) in opposite directions, and thus the driving system and the detection system can be separated. By separating the driving system and the detection system in this way, it is possible to reduce electrostatic bonding between the electrodes or the wires of the driving system and the detection system and it is possible to stabilize detection sensitivity.

In this form, the configuration in which one through hole 58a is formed in the detection arm 3a and one through hole 58b is formed in the detection arm 3b has been described, but the plurality of through holes 58a and 58b may be formed in the detection arms 3a and 3b, respectively.

### 3. Method of Manufacturing Gyro Element

Next, an example of a method of manufacturing the gyro element 300 according to the first embodiment of the above-described vibrator component will be described with reference to FIGS. 6, 7A, and 7B. FIG. 6 is a flowchart illustrating processes of the method of manufacturing the gyro element (H type gyro element) according to the first embodiment. FIG. 7A is a sectional view illustrating an exposure direction in the method of manufacturing the gyro element (H type gyro element) and corresponding to the sectional view taken along the line A-A of FIG. 1 in one detection arm according to the first embodiment. FIG. 7B is a sectional view illustrating an exposure state at ends of the through holes. In FIGS. 7A and 7B, the detection arm 3a will be exemplified in the description. The same applies to the detection arm 3b. In the following description, constituent portions of the gyro element 300 will be described using the same reference numerals with reference to FIGS. 1 to 5. The manufacturing method to be described below is merely an example and the gyro element 300 can also be manufactured by applying another manufacturing method.

As illustrated in FIG. 6, the method of manufacturing the gyro element 300 includes the following processes. The method of manufacturing the gyro element 300 includes a process (step S101) of preparing the base material, a process (step S102) of forming a metal film on the base material, a process (step S103) of forming a resist on the base material, a process (steps S104 to S107) of exposing the resist, a process (step S108) of developing and patterning the resist, and a process (step S109) of dividing the metal film. Hereinafter, the details of the processes will be described in sequence according to the flowchart of the processes illustrated in FIG. 6.

### Process (Step S101) of Preparing Base Material

First, a substrate (quartz crystal wafer) which is a base material of the gyro element 300 is prepared. The substrate (quartz crystal wafer) is a so-called quartz crystal Z plate that is cut along a plane defined by the X and Y axes in the rectangular coordinate system formed by the X, Y, and Z axes which are quartz crystal axes to be processed in a flat plate shape and has a predetermined thickness in the Z axis direction perpendicular to the plane. The substrate (quartz crystal wafer) is formed by cutting and polishing the cut quartz crystal Z plate in a predetermined thickness. The prepared substrate (quartz crystal wafer) is processed using a photolithographic method, a wet etching method, or the like to prepare the base material of the gyro element 300 with the demarcated outer shape (step S101).

### Process (Step S102) of Forming Metal Film

Next, a metal film which is formed of a conductive material and becomes electrodes later is formed on a surface (external front surface) exposed in the base material of the gyro element 300 with the demarcated outer shape by, for example, a sputtering method or an evaporation method. As the material of the metal film, for example, a conductive material such as indium tin oxide (ITO) or a metal material such as gold (Au), a gold alloy, platinum (Pt), aluminum (Al), an aluminum alloy, silver (Ag), a silver alloy, chromium (Cr), a chromium alloy, copper (Cu), molybdenum (Mo), niobium (Nb), tungsten (W), iron (Fe), titanium (Ti), cobalt (Co), zinc (Zn), or zirconium (Zr) can be used. An underlying layer formed of chromium (Cr), a chromium alloy, nickel (Ni), or the like may be formed.

### Process (Step S103) of Forming Resist

Next, a resist demarcating a mask used to form (divide) various electrodes is formed to cover the metal film of the base material of the gyro element 300 in which the metal film is formed (step S103). The forming of the resist includes a process of applying a resist resin to cover the metal film and a process of drying and hardening the applied resist resin.

### Processes (Steps S104 to S107) of Exposing Resist

Next, the process proceeds to a process of radiating light to the resist formed on the base material of the gyro element 300 via, for example, a glass mask and exposing the resist so that regions in which the various electrodes are to be formed and other regions are separated. In order to perform the exposure on the inside of the through hole 58a sufficiently and reliably, the processes (steps S104 to S107) of exposing the resist are performed 4 times while changing the radiation direction of the light. Specifically, exposure processes including a first exposure process (step S104) of exposing the resist in a direction of arrows L1 illustrated in FIG. 7A, a second exposure process (step S105) of exposing the resist in a direction of arrows L2, a third exposure process (step S106) of exposing the resist in a direction of arrows L3, and a fourth exposure process (step S107) of exposing the resist in a direction of arrows L4 are performed 4 times.

In the first exposure process (step S104) of exposing the resist in the direction of the arrows L1 illustrated in FIG. 7A (a direction oriented from the +X axis direction to the −X axis direction and oriented from the oblique upper side to the oblique lower side of the drawing), the light is radiated toward the middles of the internal surface 26h and the side surface 3i of the through hole 58a of the detection arm 3a in the thickness direction (the Z axis direction). In other words, in the first exposure process (step S104), the light is radiated from the front surface side of the detection arm 3a. At this time, on the end side surface 58c of the through hole 58a, the light is also radiated to the surface which can be viewed in the +X axis direction to perform the simultaneous exposure with the internal surface 26h. However, since the width of the through hole 58a is narrow and the wall 3e located on a light invasion side becomes a light-shielding wall, the upper portion (the front surface side) of the internal surface 26h is sufficiently exposed, but the lower portion (the rear surface side) of the internal surface 26h is rarely sufficiently exposed. Accordingly, in the first exposure process (step S104) of exposing the resist in the direction of the arrows L1, as illustrated in FIG. 7B, a portion of a region P1 (indicated by a two-dot chain line) including the upper portion (the front surface side) of the internal surface 26h and the upper portion (the front surface side) of the end side surface 58c is exposed. Although not illustrated, the same exposure is also performed on the other end side surface 58d.

Similarly, in the second exposure process (step S105) of exposing the resist in the direction of the arrows L2 illustrated in FIG. 7A (a direction oriented from the −X axis direction to the +X axis direction and oriented from the oblique upper side to the oblique lower side of the drawing), the light is radiated toward the middles of the internal surface 26i and the side surface 3h of the through hole 58a of the detection arm 3a in the thickness direction (the Z axis direction). In other words, in the second exposure process (step S105), the light is radiated from the front surface side of the detection arm 3a. At this time, on the end side surface 58c of the through hole 58a, the light is also radiated to the surface which can be viewed in the −X axis direction to perform the simultaneous exposure with the internal surface 26i. However, since the width of the through hole 58a is narrow and the wall 3d located on a light invasion side becomes a light-shielding wall, the upper portion (the front surface side) of the internal surface 26i is sufficiently exposed, but the lower portion (the rear surface side) of the internal surface 26i is rarely sufficiently exposed. Accordingly, in the second exposure process (step S105) of exposing the resist in the direction of the arrows L2, as illustrated in FIG. 7B, a portion of a region P2 (indicated by a two-dot chain line) including the upper portion (the front surface side) of the internal surface 26i and the upper portion (the front surface side) of the end side surface 58c is exposed. Although not illustrated, the same exposure is also performed on the other end side surface 58d.

Similarly, in the third exposure process (step S106) of exposing the resist in the direction of the arrows L3 illustrated in FIG. 7A (a direction oriented from the +X axis direction to the −X axis direction and oriented from the oblique lower side to the oblique upper side of the drawing), the light is radiated toward the middles of the internal surface 26h and the side surface 3i of the through hole 58a of the detection arm 3a in the thickness direction (the Z axis direction). In other words, in the third exposure process (step S106), the light is radiated from the rear surface side of the detection arm 3a. At this time, as in the above-described first exposure process (step S104), on the end side surface 58c of the through hole 58a, the light is also radiated to the surface which can be viewed in the +X axis direction to perform the simultaneous exposure with the internal surface 26h. However, as described above, since the wall 3e located on a light invasion side becomes a light-shielding wall, the lower portion (the rear surface side) of the internal surface 26h is sufficiently exposed, but the upper portion (the front surface side) of the internal surface 26h is rarely sufficiently exposed. Accordingly, in the third exposure process (step S106) of exposing the resist in the direction of the arrows L3, as illustrated in FIG. 7B, a portion of a region P3 (indicated by a one-dot chain line) including the lower portion (the rear surface side) of the internal surface 26h and the lower portion (the rear surface side) of the end side surface 58c are exposed. Although not illustrated, the same exposure is also performed on the other end side surface 58d.

Similarly, in the fourth exposure process (step S107) of exposing the resist in the direction of the arrows L4 illustrated in FIG. 7A (a direction oriented from the −X axis direction to the +X axis direction and oriented from the oblique lower side to the oblique upper side of the drawing), the light is radiated toward the middles of the internal surface 26i and the side surface 3h of the through hole 58a of the detection arm 3a in the thickness direction (the Z axis direction). In other words, in the fourth exposure process (step S107), the light is radiated from the rear surface side of the detection arm 3a. At this time, as in the above-described second exposure process (step S105), on the end side surface 58c of the through hole 58a, the light is also radiated to the surface which can be viewed in the −X axis direction to perform the simultaneous exposure with the internal surface 26i. However, as described above, since the wall 3d located on a light invasion side becomes a light-shielding wall, the lower portion (the rear surface side) of the internal surface 26i is sufficiently exposed, but the upper portion (the front surface side) of the internal surface 26i is rarely sufficiently exposed. Accordingly, in the fourth exposure process (step S107) of exposing the resist in the direction of the arrows L4, as illustrated in FIG. 7B, a portion of a region P4 (indicated by a one-dot chain line) including the lower portion (the rear surface side) of the internal surface 26i and the lower portion (the rear surface side) of the end side surface 58c are exposed. Although not illustrated, the same exposure is also performed on the other end side surface 58d.

### Process (Step S108) of Developing and Patterning Resist

Next, in the process (step S108) of developing and patterning the resist, a process of developing the resist exposed in the above-described processes is performed and the developed resist is used as an etching mask to perform patterning. In this patterning, the resist of the portions corresponding to the various electrodes formed in the gyro element 300 is remained, and the resist of portion in which no electrode is formed is removed. Thus, the metal film of the portion corresponding to the portion in which no electrode is formed, in other words, the portion corresponding to the electrode division portion 26d, is exposed.

### Process (Step S109) of Dividing Metal Film

Next, the exposed metal film is removed by wet etching with the patterned resist as an etching mask using, for example, an etchant of potassium iodide or the like. Thus, the metal film to be removed is all removed by the etching, and thus the metal film is divided (step S109). Thereafter, by exfoliating all of the unnecessary resist, the metal film of the portions in which the resist is formed is exposed, and thus the first detection electrode 21a, the second detection electrode 21b, the third detection electrode 22a, the fourth detection electrode 22b, and the electrodes of the first wire 25 and the second wire 27 which are the various electrodes are formed.

According to the manufacturing method of the above-described gyro element 300, the metal film is formed on the exposed surface of the detection arm 3a serving as the first vibration arm in which the through hole 58a is formed and the metal film is divided on the end side surface 58c (the end side surface 58d) and the internal surfaces 26h and 26i of the through hole to form the electrodes (the first detection electrode 21a, the second detection electrode 21b, the third detection electrode 22a, the fourth detection electrode 22b, the first wire 25, and the second wire 27). In this way, since the first wire 25 and the second wire 27 can be formed on the end side surface 58c (the end side surface 58d), the first detection electrode 21a serving as the first electrode, the second detection electrode 21b serving as the second electrode, and the first wire 25 connecting these electrodes can be easily formed in, for example, the through hole 58a without forming wires in narrow regions of the front and rear surfaces of the detection arm 3a. Further, since the width of the first wire 25 can be easily widened, it is possible to suppress disconnection of the wire easily occurring in the wire with a narrow width.

By disposing the electrode division portions 26a, 26b, 28a, and 28b to reach the front and rear surfaces of the detection arm 3a in the middle of the end side surface 58c (the end side surface 58d) in the X direction, it is possible to expose the electrode division portions 26a, 26b, 28a, and 28b once from the oblique upper side or the oblique lower side, and thus it is possible to simplify the exposure process.

The same manufacturing method can also be applied to the detection arm 3b, and thus the same advantages can be obtained.

Since the exposure is performed in four directions in the exposure processes (steps S104 to S107) performed 4 times, it is possible to sufficiently expose the resist in the through hole 58a of the narrow region. Since the metal film is divided using the resist as the etching mask to form the electrodes (the first detection electrode 21a, the second detection electrode 21b, the third detection electrode 22a, the fourth detection electrode 22b, the first wire 25, and the second wire 27), it is possible to suppress occurrence of a defect of the division in the forming of the electrodes.

Since the wire (the first wire 25) is formed in the end side surface 58c present inside the through hole 58a, it is difficult to radiate, for example, a laser beam used at the time of subsequent frequency adjustment. Thus, it is possible to suppress occurrence of a defect such as cutting of the wire due to erroneous radiation of the laser beam to the wire.

### Second Embodiment

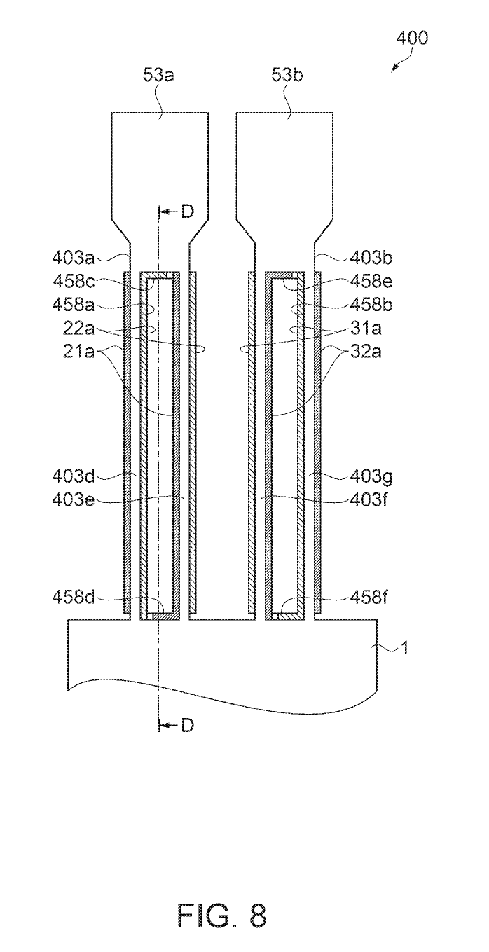

A gyro element (H type gyro element) serving as a vibrator component according to a second embodiment of the vibrator device according to the invention will be described. First, the configuration of the gyro element (H type gyro element) will be described with reference to FIG. 8. FIG. 8 is a partial plan view illustrating an overview of the gyro element (H type gyro element) serving as a vibrator component according to the second embodiment of the vibrator device. In FIG. 8, portions of a detection arm with a different configuration from the above-described first embodiment are mainly drawn in the gyro element (H type gyro element). Hereinafter, the same reference numerals are given to the same configurations as those of the above-described first embodiment, and the description thereof will be omitted.

### 1. Configuration of Gyro Element

As illustrated in FIG. 8, a gyro element 400 according to the second embodiment includes abase 1, vibration arms (not illustrated in FIG. 8) serving as a second vibration arm, and detection arms 403a and 403b serving as a first vibration arm which are formed in an integrated manner by processing a base material (a material of main portions). The gyro element 400 according to the second embodiment is different from the gyro element 300 according to the first embodiment in configurations of through holes 458a and 458b formed in the detection arms 403a and 403b. Hereinafter, the detection arms 403a and 403b and the through holes 458a and 458b with different configurations will be described mainly.

The through holes 458a and 458b are formed in a pair of detection arms 403a and 403b. Specifically, the through hole 458a is formed in the detection arm 403a and the through hole 458b is formed in the detection arm 403b. The through holes 458a and 458b are penetrated through the front and rear surfaces of the detection arms 403a and 403b to be arranged in the extension direction (the Y axis direction) of the detection arms 403a and 403b. The through holes 458a and 458b are penetrated through the front and rear surfaces in the middles of the pair of detection arms 403a and 403b in a plan view. In the detection arms 403a and 403b, walls 403d, 403e, 403f, and 403g are formed on both sides in the width direction (the X axis direction) by the through holes 458a and 458b with the through holes 458a and 458b interposed therebetween. Specifically, the detection arm 403a includes the walls 403d and 403e on both sides with the through hole 458a interposed therebetween. The detection arm 403b includes the walls 403f and 403g on both sides with the through hole 458b interposed therebetween.

The through holes 458a and 458b include first end portions located on the side of the base 1 and second end portions located on the opposite side (the side of the weights 53a and 53b) to the first end portions. The first end portions include end side surfaces 458d and 458f which are the other end side surfaces and the second end portions include end side surfaces 458c and 458e which are one end side surfaces. The end side surfaces 458c, 458d, 458e, and 458f are surfaces that connect two internal surfaces of the through holes 458a and 458b facing each other in the extension direction (the Y axis direction) in the internal surfaces of the through holes 458a and 458b and are said to be portions of the internal surfaces located in both of the first and second end portions in the Y axis direction.

### 2. Electrode Disposition of Gyro Element

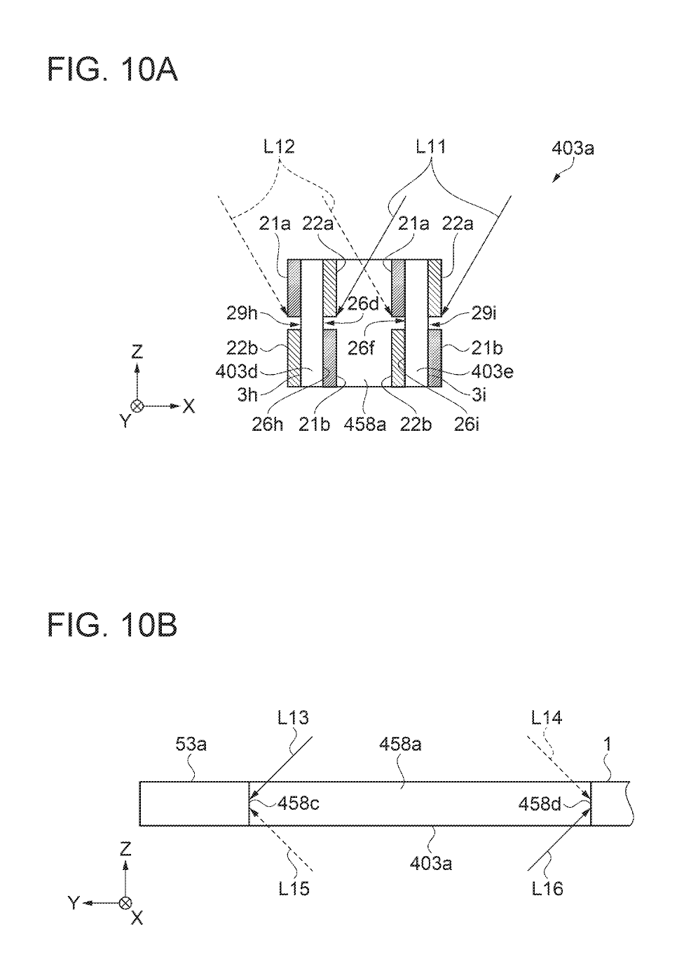

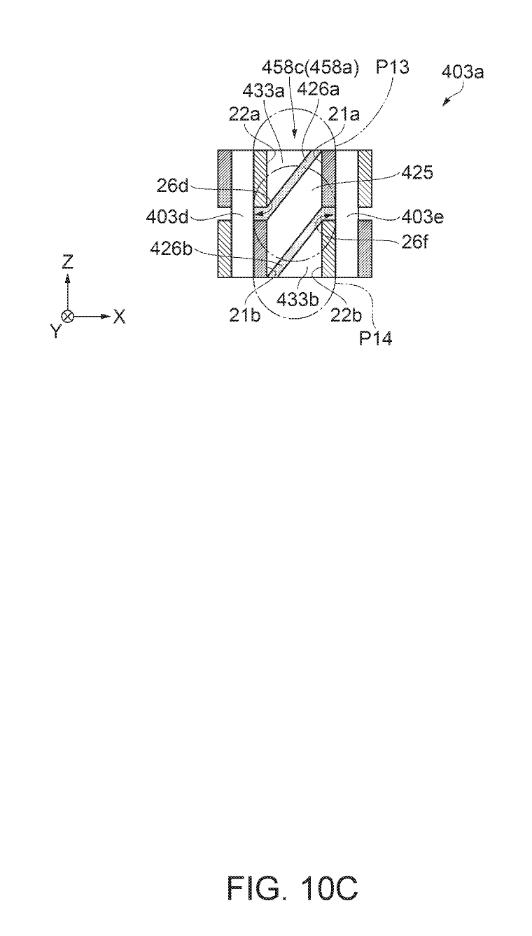

Next, an embodiment of electrode disposition of the gyro element 400 will be described. As in the above-described first embodiment, the gyro element 400 includes various electrodes corresponding to the drive electrodes 11a, 11b, 11c, 12a, 12b, 12c, the first detection electrode 21a, the second detection electrode 21b, the third detection electrode 22a, the fourth detection electrode 22b, the fifth detection electrode 31a, the sixth detection electrode 31b, the seventh detection electrode 32a, the eighth detection electrode 32b, the first wires 25 and 35, and the second wires 27 and 37. The electrodes are disposed as in the above-described first embodiment. Thus, the detailed description will be omitted. The electrodes formed in the detection arm 403a are exemplified in FIG. 10B. In FIG. 10C, a wire corresponding to the first wire 25 is numbered as a first wire 425.

In the gyro element 400, the first wire 425 (see FIG. 10C) is formed in the end side surface 458c disposed in the Y axis direction. Although not illustrated, similarly, a second wire is formed in the end side surface 458d disposed in the Y axis direction.

In the gyro element 400 including the through holes 458a and 458b with such configurations, as in the above-described first embodiment, the first wire 425 (see FIG. 10C) and the second wire (not illustrated) are disposed in the end side surfaces 458c and 458d. In this way, when the first wire 425 and the second wire (not illustrated) are disposed on the end side surfaces 458c, 458d, 458e, and 458f of the through holes 458a and 458b, it is not necessary to form wires corresponding to the first wire 425 (the second wire) in narrow regions of the front and rear surfaces. Thus, the width of the wire (the first wire 425 or the second wire) connecting the electrodes formed in the two internal surfaces 26h and 26i (see FIG. 10A) can be widened. Since the wire (the first wire 425 or the second wire) is formed on the end side surfaces 458c, 458d, 458e, and 458f present inside the through holes 458a and 458b, it is difficult to radiate, for example, a laser beam used at the time of frequency adjustment or the like by comparison of the front and rear surfaces. Thus, it is possible to suppress occurrence of a defect such as cutting of the wires.

In this form, the configuration in which one through hole 458a is formed in the detection arm 403a and one through hole 458b is formed in the detection arm 403b has been described, but the plurality of through holes 458a and 458b may be formed in the detection arms 403a and 403b, respectively.

### 3. Method of Manufacturing Gyro Element

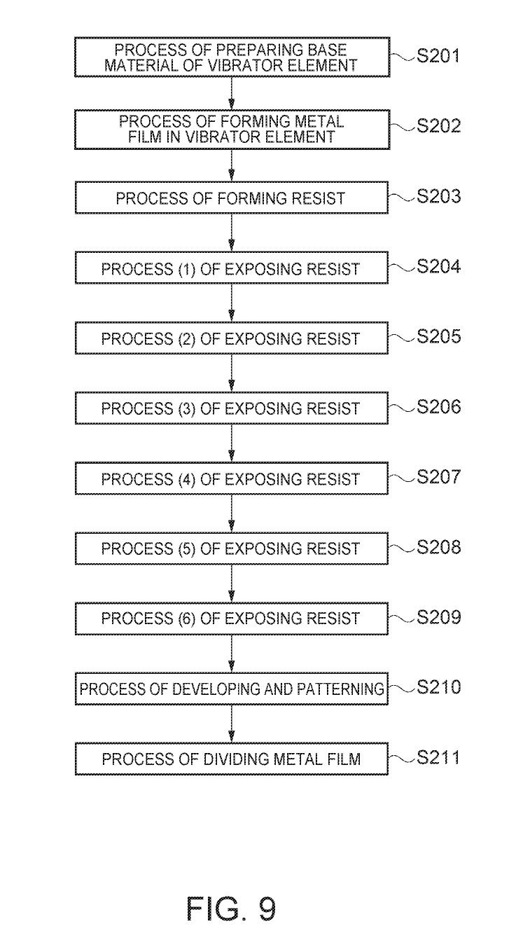

Next, an example of a method of manufacturing the gyro element 400 according to the second embodiment of the above-described vibrator component will be described with reference to FIGS. 9, 10A, 10B, and 10C. FIG. 9 is a flowchart illustrating processes of the method of manufacturing the gyro element (H type gyro element) according to the second embodiment. FIG. 10A is a sectional view illustrating an exposure direction in the method of manufacturing the gyro element (H type gyro element) and corresponding to the sectional view taken along the line A-A of FIG. 1 in one detection arm according to the second embodiment. FIG. 10B is a sectional view illustrating an exposure direction in the method of manufacturing the gyro element (H type gyro element) and corresponding to the sectional view taken along the line D-D of FIG. 8 in one detection arm according to the second embodiment. FIG. 10C is a sectional view illustrating an exposure state at ends of the through holes. In FIGS. 10A, 10B, and 10C, the detection arm 403a will be exemplified in the description. The same applies to the detection arm 403b. In the following description, constituent portions of the gyro element 400 will be described using the same reference numerals with reference to FIG. 8. The manufacturing method to be described below is merely an example and the gyro element 400 can also be manufactured by applying another manufacturing method.

As illustrated in FIG. 9, the method of manufacturing the gyro element 400 includes the following processes. The method of manufacturing the gyro element 400 includes a process (step S201) of preparing the base material, a process (step S202) of forming a metal film on the base material, a process (step S203) of forming a resist on the base material, a process (steps S204 to S209) of exposing the resist, a process (step S210) of developing and patterning the resist, and a process (step S211) of dividing the metal film. Hereinafter, the details of the processes will be described in sequence according to the flowchart of the processes illustrated in FIG. 9. The description of the process (step S201) of preparing the base material, the process (step S202) of forming a metal film on the base material, the process (step S203) of forming a resist on the base material, the process (step S210) of developing and patterning the resist, and the process (step S211) of dividing the metal film which are substantially the same processes as those of the above-described first embodiment will be omitted.

First, as in the first embodiment, in the process (step S202) of forming the metal film, the metal film is formed on the exposed surface of the base material of the gyro element 400 prepared in the process (step S201) of preparing the base material, and the resist demarcating the mask used to form (divide) the electrodes is formed to cover the metal film in the process (step S203) of forming the resist.

### Processes (Steps S204 to S209) of Exposing Resist

Next, the process proceeds to a process of radiating light to the resist formed on the base material of the gyro element 400 via, for example, a glass mask and exposing the resist so that regions in which the various electrodes are to be formed and other regions are separated. In order to perform the exposure on the inside of the through hole 458a sufficiently and reliably, the processes of exposing the resist are performed 6 times while changing the radiation direction of the light. Specifically, exposure processes including a first exposure process (step S204) of exposing the resist in a direction of arrows L11 illustrated in FIG. 10A, a second exposure process (step S205) of exposing the resist in a direction of arrows L12, a third exposure process (step S206) of exposing the resist in a direction of an arrow L13 illustrated in FIG. 10B, a fourth exposure process (step S207) of exposing the resist in a direction of an arrow L14, a fifth exposure process (step S208) of exposing the resist in a direction of an arrow L15, and a sixth exposure process (step S209) of exposing the resist in a direction of an arrow L16 are performed 6 times.

In the first exposure process (step S204) of exposing the resist in the direction of the arrows L11 illustrated in FIG. 10A (a direction oriented from the +X axis direction to the −X axis direction and oriented from the oblique upper side to the oblique lower side of the drawing), the light is radiated toward the middles of the internal surface 26h and the side surface 3i of the through hole 458a of the detection arm 403a in the thickness direction (the Z axis direction). In other words, in the first exposure process (step S204), the light is radiated from the front surface side of the detection arm 403a. In this configuration, the middle of the internal surface 26h of the through hole 458a in the thickness direction (the Z axis direction) is a portion in which the electrodes are divided. Accordingly, even when the width of the through hole 458a is narrow, sufficient exposure can be performed on the divided portion (the electrode division portion 26d) of the internal surface 26h without interruption (light shielding) of the wall 403e located on a light invasion side.

Similarly, in the second exposure process (step S205) of exposing the resist in the direction of the arrows L12 illustrated in FIG. 10A (a direction oriented from the −X axis direction to the +X axis direction and oriented from the oblique upper side to the oblique lower side of the drawing), the light is radiated toward the middles of the internal surface 26i and the side surface 3h of the through hole 458a of the detection arm 403a in the thickness direction (the Z axis direction). In other words, in the second exposure process (step S205), the light is radiated from the front surface side of the detection arm 403a. In this configuration, as in the first exposure process (step S204), the middle of the internal surface 26i of the through hole 458a in the thickness direction (the Z axis direction) is a portion in which the electrodes are divided. Accordingly, even when the width of the through hole 458a is narrow, sufficient exposure can be performed on the divided portion (the electrode division portion 26f) of the internal surface 26i without interruption (light shielding) of the wall 403d located on a light invasion side.

Similarly, in the third exposure process (step S206) of exposing the resist in the direction of the arrow L13 illustrated in FIG. 10B (a direction oriented from the −Y axis direction to the +Y axis direction and oriented from the oblique upper side to the oblique lower side of the drawing), the light is radiated toward the middle of the end side surface 458c of the through hole 458a of the detection arm 403a in the thickness direction (the Z axis direction). In other words, in the third exposure process (step S206), the light is radiated from the front surface side of the detection arm 403a. At this time, since the width of the through hole 458a is narrow, the sufficient light reaches the upper portion (the front surface side) of the end side surface 458c so that the upper portion is exposed, but the sufficient light rarely reaches the lower portion (the rear surface side) of the end side surface 458c so that the lower portion is rarely sufficiently exposed. Accordingly, in the third exposure process (step S206) of exposing the resist in the direction of the arrow L13, as illustrated in FIG. 10C, a region P13 (indicated by a two-dot chain line) including the upper portion (the front surface side) of the end side surface 458c is exposed.

Similarly, in the fourth exposure process (step S207) of exposing the resist in the direction of the arrow L14 illustrated in FIG. 10B (a direction oriented from the +Y axis direction to the −Y axis direction and oriented from the oblique upper side to the oblique lower side of the drawing), the light is radiated toward the middle of the end side surface 458d of the through hole 458a of the detection arm 403a in the thickness direction (the Z axis direction). In other words, in the fourth exposure process (step S207), the light is radiated from the front surface side of the detection arm 403a. At this time, since the width of the through hole 458a is narrow, the sufficient light reaches the upper portion (the front surface side) of the end side surface 458d so that the upper portion is exposed, but the sufficient light rarely reaches the lower portion (the rear surface side) of the end side surface 458d so that the lower portion is rarely sufficiently exposed. Accordingly, in the fourth exposure process (step S207) of exposing the resist in the direction of the arrow L14, a region (not illustrated) of the end side surface 458d corresponding to a portion such as the region P13 including the upper portion (the front surface side) of the end side surface 458c illustrated in FIG. 10C is exposed.

Similarly, in the fifth exposure process (step S208) of exposing the resist in the direction of the arrow L15 illustrated in FIG. 10B (a direction oriented from the −Y axis direction to the +Y axis direction and oriented from the oblique lower side to the oblique upper side of the drawing), the light is radiated toward the middle of the end side surface 458c of the through hole 458a of the detection arm 403a in the thickness direction (the Z axis direction). In other words, in the fifth exposure process (step S208), the light is radiated from the rear surface side of the detection arm 403a. At this time, since the width of the through hole 458a is narrow, the sufficient light reaches the lower portion (the rear surface side) of the end side surface 458c so that the lower portion is exposed, but the sufficient light rarely reaches the upper portion (the front surface side) of the end side surface 458c so that the upper portion is rarely sufficiently exposed. Accordingly, in the fifth exposure process (step S208) of exposing the resist in the direction of the arrow L15, as illustrated in FIG. 10C, a region P14 (indicated by a one-dot chain line) including the lower portion (the rear surface side) of the end side surface 458c is exposed.

Similarly, in the sixth exposure process (step S209) of exposing the resist in the direction of the arrow L16 illustrated in FIG. 10B (a direction oriented from the +Y axis direction to the −Y axis direction and oriented from the oblique lower side to the oblique upper side of the drawing), the light is radiated toward the middle of the end side surface 458d of the through hole 458a of the detection arm 403a in the thickness direction (the Z axis direction). In other words, in the sixth exposure process (step S209), the light is radiated from the rear surface side of the detection arm 403a. At this time, since the width of the through hole 458a is narrow, the sufficient light reaches the lower portion (the rear surface side) of the end side surface 458d so that the lower portion is exposed, but the sufficient light rarely reaches the upper portion (the front surface side) of the end side surface 458d so that the upper portion is rarely sufficiently exposed. Accordingly, in the sixth exposure process (step S209) of exposing the resist in the direction of the arrow L16, a region (not illustrated) of the end side surface 458d corresponding to a portion such as the region P14 including the lower portion (the rear surface side) of the end side surface 458c illustrated in FIG. 10C is exposed.

### Process (Step S210) of Developing and Patterning Resist

Next, the process of developing the resist exposed in the above-described processes (steps S204 to S209) of exposing the resist is performed. Then, the process proceeds to the process (step S210) of developing and patterning the resist patterned using the developed resist as an etching mask. The process (step S210) of developing and patterning the resist is the same as that of the first embodiment, and thus the description thereof will be omitted.

### Process (Step S211) of Dividing Metal Film

Next, the process proceeds to the process (step S211) of dividing the metal film in which the exposed metal film is removed by wet etching with the patterned resist as an etching mask using, for example, an etchant of potassium iodide or the like. The process (step S211) of dividing the metal film is the same as that of the first embodiment, and thus the description thereof will be omitted. Through the process (step S211), the first detection electrode 21a, the second detection electrode 21b, the third detection electrode 22a, the fourth detection electrode 22b, the first wire 425, and the second wire (not illustrated) which are the various electrodes are formed.

According to the method of manufacturing the above-described gyro element 400, the metal film is formed on the exposed surface of the detection arm 403a serving as the first vibration arm in which the through hole 458a is formed and the metal film is divided on the end side surface 458c (the end side surface 458d) and the internal surfaces 26h and 26i of the through hole to form the electrodes (the first detection electrode 21a, the second detection electrode 21b, the third detection electrode 22a, the fourth detection electrode 22b, the first wire 425, and the second wire (not illustrated)). In this way, since the first wire 425 and the second wire (not illustrated) can be formed on the end side surface 458c (the end side surface 458d), the first detection electrode 21a serving as the first electrode, the second detection electrode 21b serving as the second electrode, and the first wire 425 connecting these electrodes can be easily formed in, for example, the through hole 458a without forming wires in narrow regions of the front and rear surfaces of the detection arm 403a. Further, since the width of the first wire 425 can be easily widened, it is possible to suppress disconnection of the wire easily occurring in the wire with a narrow width. The same manufacturing method can be applied to the detection arm 403b, and thus the same advantages can be obtained.

Since the exposure is performed in the exposure processes (steps S204 to S209) performed 6 times, it is possible to sufficiently expose the resist in the through hole 458a of the narrow region. Since the metal film is divided using the resist as the etching mask to form the electrodes (the first detection electrode 21a, the second detection electrode 21b, the third detection electrode 22a, the fourth detection electrode 22b, the first wire 425, and the second wire (not illustrated)), it is possible to suppress occurrence of a defect of the division in the forming of the electrodes.

Since the wires (the first wire 425 and the like) are formed in the end side surfaces 458c and 458d present inside the through hole 458a, it is difficult to radiate, for example, a laser beam used at the time of subsequent frequency adjustment. Thus, it is possible to suppress occurrence of a defect such as cutting of the wire.

### Third Embodiment

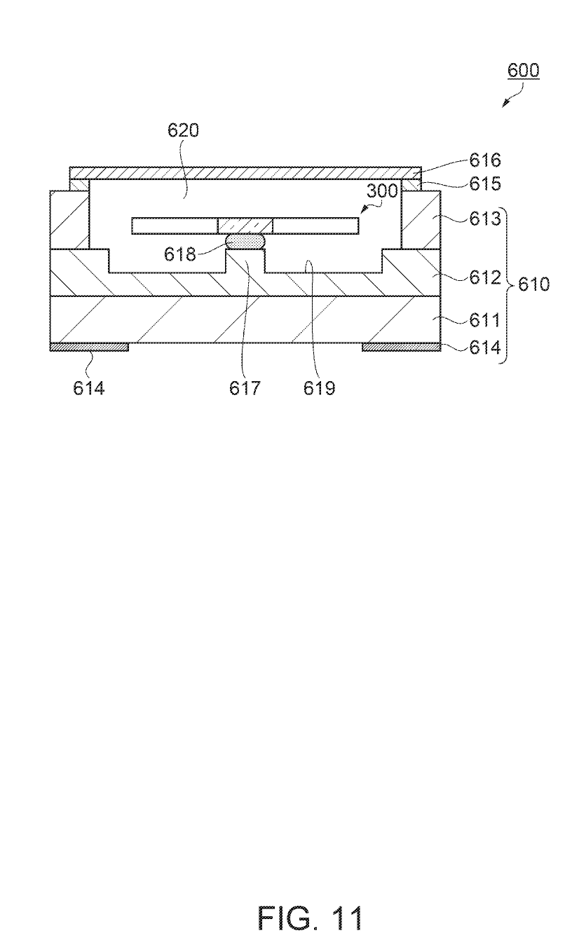

Next, a gyro sensor according to a third embodiment of the vibrator device according to the invention will be described with reference to FIG. 11. FIG. 11 is a front sectional view illustrating an overall configuration of the gyro sensor according to the third embodiment of the vibrator device according to the invention. For example, a gyro sensor 600 according to the third embodiment of the vibrator device illustrated in FIG. 11 is configured to include the gyro element (H type gyro element) 300 that includes at least the detection arms 3a and 3b serving as the first vibration arm, as described above in the first embodiment.

As illustrated in FIG. 11, the gyro sensor 600 accommodates the gyro element 300 in a depressed portion of a package 610 and an opening of the package 610 is sealed by a lid 616 so that the inside is maintained airtightly. The package 610 is formed by stacking and fastening a first substrate 611 with a flat plate shape, a second substrate 612, a third substrate 613 with a frame shape, and mounting terminals 614. The plurality of mounting terminals 614 are formed on the external bottom surface of the first substrate 611. The second substrate 612 is stacked on the upper surface of the first substrate 611 and includes a recessed portion 619 that separates the gyro element 300 and a support portion 617 that supports the gyro element 300. Wires connected to the mounting terminals 614 and connection wires with the electrodes of the gyro element 300 are formed on the upper surface of the second substrate 612 and are not illustrated. The third substrate 613 has a ring shape of which a middle portion is removed. A cavity 620 accommodating the gyro element 300 is formed in conjunction with the first substrate 611 and the second substrate 612.

The first substrate 611, the second substrate 612, and the third substrate 613 are formed of a material with an insulation property. The material is not particular limited. For example, various ceramics such as an oxide-based ceramic, a nitride-based ceramic, and a carbide-based ceramic can be used. For example, each electrode such as the above-described wire or connection wire, a terminal (not illustrated), or a wiring pattern electrically connecting the electrodes and the terminals, or a wire pattern in a layer (not illustrated) which is formed in the package 610 is formed generally by performing screen-printing a metal wire material such as tungsten (W) or molybdenum (Mo) on an insulation material, baking the metal wire material, and applying plating of nickel (Ni), gold (Au), or the like on the metal wire material.

The lid 616 blocks the opening of the package 610 and is bonded by a sealing material 615 to airtightly seal the cavity 620 of the package 610. The lid 616 can be formed of, for example, a metal material such as a Kovar alloy.

The gyro element 300 accommodated inside the cavity 620 of the package 610 is connected to the upper surface side of the support portion 617 via a bonding member 618. The bonding member 618 can perform electric connection and mechanical connection, for example, by using a conductive bonding member such as a conductive adhesive.

In the above-described gyro sensor 600, the gyro element (H type gyro element) 300 including at least the detection arms 3a and 3b serving as the first vibration arm is accommodated in the package 610. Therefore, it is difficult to have an influence of disturbance and it is possible to stabilize detection characteristics of an angular velocity.

### Electronic Apparatus

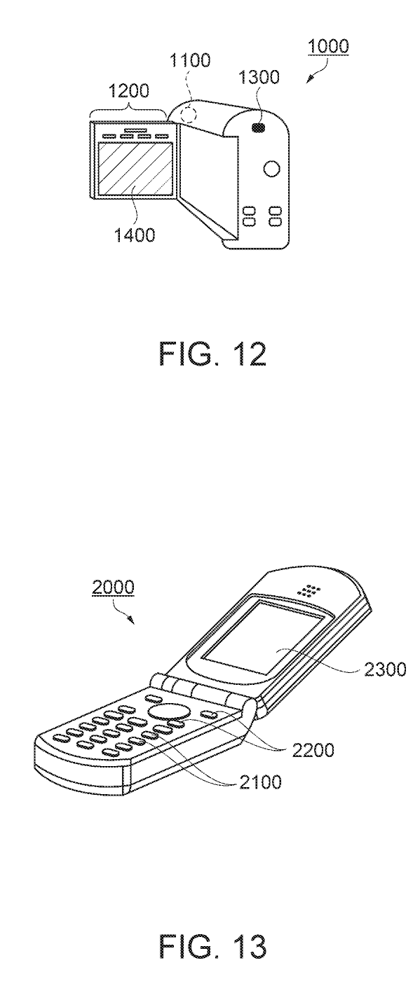

Next, electronic apparatuses including the vibrator component according to the above-described embodiments will be described with reference to FIGS. 12, 13, and 14. In the following description, an example in which the gyro element 300 is used as an example of the vibrator component will be described. FIGS. 12, 13, and 14 are perspective views illustrating examples of the electronic apparatus including the gyro element 300.

FIG. 12 illustrates an example in which the gyro element 300 is applied to a digital video camera 1000 which is an electronic apparatus. The digital video camera 1000 illustrated in FIG. 12 includes an image reception unit 1100, an operation unit 1200, an audio input unit 1300, and a display unit 1400. The digital video camera 1000 can be set to include a camera shake correction function on which the gyro element 300 according to the above-described embodiment is mounted.

FIG. 13 illustrates an example in which the gyro element 300 is applied to a mobile phone 2000 which is an electronic apparatus. The mobile phone 2000 illustrated in FIG. 13 includes a plurality of operation buttons 2100, scroll buttons 2200, and a display unit 2300. By operating the scroll buttons 2200, a screen displayed on the display unit 2300 is scrolled.

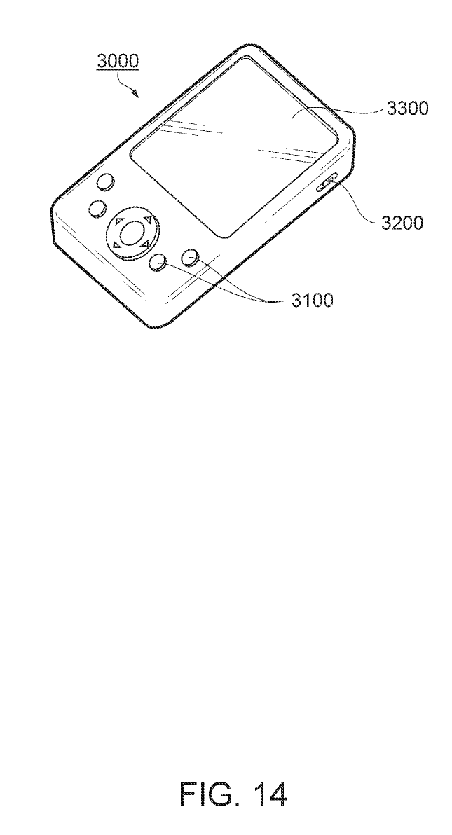

FIG. 14 illustrates an example in which the gyro element 300 is applied to an information portable terminal (PDA: personal digital assistants) 3000 which is an electronic apparatus. The PDA 3000 illustrated in FIG. 14 includes a plurality of operation buttons 3100, a power switch 3200, and a display unit 3300. When the power switch 3200 is operated, various kinds of information such as an address book or a schedule book is displayed on the display unit 3300.

By mounting the gyro element 300 according to the above-described embodiment on the mobile phone 2000 or the PDA 3000, various functions can be provided. For example, in a case in which a camera function (not illustrated) is provided in the mobile phone 2000 in FIG. 13, camera shake correction can be performed as in the forgoing digital video camera 1000. In a case in which the well-known Global Positioning System (GPS) is included in the mobile phone 2000 in FIG. 13 or the PDA 3000 in FIG. 14, the gyro element 300 according to the above-described embodiment can be mounted so that the position or posture of the mobile phone 2000 or the PDA 3000 can be recognized by the GPS.

A vibrator component, the gyro element 300 according to the embodiment of the invention is an example thereof, can be applied not only to the digital video camera 1000 in FIG. 12, the mobile phone in FIG. 13, and the information portable terminal in FIG. 14 but also to, for example, an inkjet ejection apparatus (for example, an ink jet printer), a laptop personal computer, a tablet personal computer, a storage area network apparatus such as a router or a switch, a local area network apparatus, a mobile terminal base station apparatus, a television, a video camera, a video tape recorder, a car navigation apparatus, a real-time clock apparatus, a pager, an electronic organizer (also including a communication function unit), an electronic dictionary, a calculator, an electronic game apparatus, a word processor, a workstation, a television phone, a security television monitor, electronic binoculars, a POS terminal, medical apparatuses (for example, an electronic thermometer, a blood pressure meter, a blood-sugar meter, an electrocardiographic apparatus, an ultrasonic diagnostic apparatus, and an electronic endoscope), a fish finder, various measurement apparatuses such as a gas meter, a water meter, and an electric energy meter (smart meter) having a wired or wireless communication function and capable of transmitting various kinds of data, meters (for example, meters for vehicles, airplanes, and ships), a flight simulator, a head-mounted display, a motion trace, a motion tracking, a motion controller, and a PDR (pedestrian position azimuth measurement).

### Moving Object

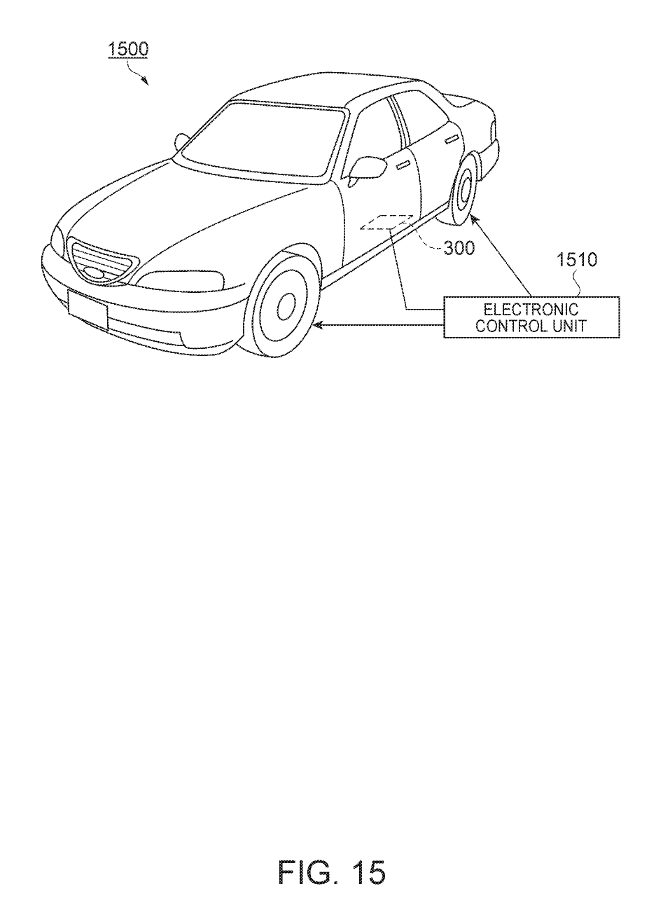

Next, a moving object including the vibrator component according to the above-described embodiment will be described. In the following description, an example in which the gyro element 300 is used as an example of the vibrator component will be described. FIG. 15 is a perspective view schematically illustrating an automobile which is an example of a moving object. The gyro element 300 is mounted on an automobile 1500. For example, as illustrated in the drawing, an electronic control unit 1510 that contains the gyro element 300 and controls tires or the like is mounted on the automobile 1500 which is a moving object. The gyro element 300 can also be applied widely to an electronic control unit (ECU) such as a keyless entry, an immobilizer, a car navigation system, a car air conditioner, an antilock brake system (ABS), an air bag, a tire pressure monitoring system (TPMS), an engine control, a cell monitor of a hybrid automobile or an electric automobile, or a vehicle attitude controlling system.

The embodiments have been described specifically above. However, the invention is not limited to the foregoing embodiments and various modifications can be made within the scope of the invention without depart from the gist of the invention. For example, in the foregoing embodiments and modification examples, the examples in which quartz crystal is used as a forming material of the vibrator component or the gyro element serving as the vibrator component have been described, but a piezoelectric material other than quartz crystal can be used. For example, an oxide substrate formed of aluminum nitride (AlN), lithium niobate (LiNbO₃), lithium tantalate (LiTaO₃), lead zirconate titanate (PZT), lithium tetraborate (Li₂B₄O₇), and langasite crystal (La₃Ga₅SiO₁₄) can be used. Alternatively, a stacked piezoelectric substrate formed by stacking a piezoelectric material such as aluminum nitride or tantalum pentoxide (Ta2O₅) on a glass substrate, a piezoelectric ceramics, or the like can be used.

The gyro element is not limited to the exemplified H type gyro element. For example, the invention can be applied to other gyro elements such as a double T type gyro element, a tuning-fork type gyro element. The vibrator component can be formed using a material other than a piezoelectric material. For example, the vibrator component can also be formed using a silicon semiconductor material or the like. The vibration (driving) type of vibrator component is not limited to the piezoelectric driving. The configurations and the advantages of the invention can be achieved not only in the piezoelectric driving type vibrator component using a piezoelectric substrate but also in an electrostatic driving type vibrator component using an electrostatic force or a Lorentz driving type vibrator component or the like using a magnetic force.

The entire disclosure of Japanese Patent Application No. 2015-225456, filed Nov. 18, 2015 is expressly incorporated by reference herein.

What is claimed is:

1. A vibrator device comprising:
a first vibration including
front and rear surfaces,
a through hole that is penetrated through the front and rear surfaces, and
walls located on both sides with the through hole interposed therebetween,
wherein each of the walls includes two electrodes arranged on each of two internal surfaces located on the walls of the through hole, to which mutually different potentials are applied, and which extend in parallel along the front and rear surfaces, and
of the electrodes, a first electrode located on the front surface side of one of the internal surfaces and a second electrode located on the rear surface side of the other internal surface are short-circuited by a first wire disposed on one of end side surfaces connecting the two internal surfaces.

2. The vibrator device according to claim 1,
wherein the electrodes include a second wire that short-circuits a third electrode located on the front surface side of the one internal surface and a fourth electrode located on the rear surface side of the other internal surface, and
the second wire is disposed on the other end side surface connecting the two internal surfaces.

3. The vibrator device according to claim 1,
wherein a width of the end side surface includes a portion narrower than a width between the two internal surfaces.

4. The vibrator device according to claim 1, further comprising:
a base; and
a second vibration arm that extends from the base,
wherein the first vibration arm extends from the base in an opposite direction to an extension direction of the second vibration arm.

5. The vibrator device according to claim 1, further comprising:
a package that accommodates at least the first vibration arm.

6. A method of manufacturing a vibrator device including a first vibration arm including front and rear surfaces, a through hole that is penetrated through the front and rear surfaces, walls located on both sides with the through hole interposed therebetween, in which each of the walls includes two electrodes arranged on each of two internal surfaces located on the walls of the through holes, to which mutually different potentials are applied, and which extend in parallel along the front and rear surfaces, in which each of the electrodes includes a first wire short-circuiting a first electrode located on the front surface side of one of the internal surfaces and a second electrode located on the rear surface side of the other internal surface and the first wire is disposed on one of end side surfaces of the through hole connecting the two internal surfaces, the method comprising:
forming a metal film on an exposure surface of the first vibration arm in which the through hole is formed; and
forming the electrodes by dividing the metal film on the end side surface and the internal surface.

7. The method according to claim 6,
wherein the forming of the electrodes by dividing the metal film includes exposing process performed 4 times.

8. An electronic apparatus comprising:
the vibrator device according to claim 1.

9. An electronic apparatus comprising:
the vibrator device according to claim 2.

10. An electronic apparatus comprising:
the vibrator device according to claim 3.

11. An electronic apparatus comprising:
the vibrator device according to claim 4.

12. An electronic apparatus comprising:
the vibrator device according to claim 5.

13. A moving object comprising:
the vibrator device according to claim 1.

14. A moving object comprising:
the vibrator device according to claim 2.

15. A moving object comprising:
the vibrator device according to claim 3.

16. A moving object comprising:
the vibrator device according to claim 4.

17. A moving object comprising:
the vibrator device according to claim 5.
